(19) United States
(12) Patent Application Publication
(10) Pub. No.: US 2009/0321119 A1
(43) Pub. Date: Dec. 31, 2009

(54) DEVICE MOUNTING BOARD, SEMICONDUCTOR MODULE, MOBILE DEVICE, AND MANUFACTURING METHOD OF DEVICE MOUNTING BOARD

(76) Inventors: Yasuhiro Kohara, Osaka (JP); Ryosuke Usui, Osaka (JP); Yasunori Inoue, Osaka (JP)

Correspondence Address: MCDERMOTT WILL & EMERY LLP, 600 13TH STREET, N.W., WASHINGTON, DC, 20005-3096, US

(21) Appl. No.: 12/495,028

(22) Filed: Jun. 30, 2009

(30) Foreign Application Priority Data
Jun. 30, 2008 (JP) 2008-170998
Sep. 30, 2008 (JP) 2008-254413

(51) Int. Cl. H05K 1/18; H05K 1/11

(52) U.S. Cl. 174/260; 174/261

(57) ABSTRACT

A device mounting board is provided with: a substrate structural unit including a substrate made of a composition containing amorphous silicon, a first adhesive layer provided on one of the main surfaces of the substrate, and a second adhesive layer provided on the other main surface of the substrate; a first wiring layer provided on the main surface of the first adhesive layer on the opposite side from the substrate; a second wiring layer provided on the main surface of the second adhesive layer on the opposite side from the substrate; and a via conductor, which is provided in a via hole that penetrates the substrate, the first adhesive layer, and the second adhesive layer, which electrically connects the first wiring layer and the second wiring layer.

### CROSS-REFERENCE TO RELATED APPLICATIONS

This application is based upon and claims the benefit of priority from the prior Japanese Patent Application No. 2008-170998, filed on Jun. 30, 2008, and Japanese Patent Application No. 2008-254413 filed on Sep. 30, 2008, the entire contents of which are incorporated herein by reference.

### BACKGROUND OF THE INVENTION

1. Field of the Invention

The present invention relates to device mounting boards, semiconductor modules, mobile devices, and methods of manufacturing the device mounting boards.

2. Description of the Related Art

With the accelerating trend toward multi-functional portable electronic devices such as mobile phones, PDAs, and DSCs, miniaturization and reduced weight have become essential features for these products to be competitive in the market. For this to be realized, there is a strong need for the development of highly-integrated system LSI. At the same time, more convenient, easy-to-use electronic devices are required, and there is a strong need for multi-functional and high-performance LSI to be applied to the devices. For this reason, while the number of I/Os increases with the high integration of LSI chips, there is also a strong demand for miniaturization of packages. In order to achieve a balance between them, the development of semiconductor packages suitable for high-density board mounting of semiconductor components is in strong demand.

Recently, in order to meet this demand for high density board mounting, miniaturization and layer multiplication are performed on circuit boards adapted for mounting LSI chips. For example, device mounting boards are known in which multiple resin films having fine wirings formed on one of surfaces and having an adhesive layer on the other surface are laminated via adhesive layers.

On the device mounting board, wiring layers of glass epoxy resin layers adjacent to each other are electrically connected by way of via conductors formed in via holes provided at predetermined positions of insulating resin layers, for example, a glass epoxy resin obtained by impregnating glass fibers with an epoxy resin. A glass epoxy resin layer has the thickness to provide for a certain stiffness. Thus, in the case of forming a via hole on a glass epoxy resin layer, the via hole is usually formed one by one on the glass epoxy resin layer by a drilling process or a laser process, conventionally.

However, as described above, the number of I/Os has been on the increase with the high integration of semiconductor devices. As a result, the number of via conductors that connect wiring layers has also been on the increase. Therefore, there has been an increase in the number of necessary via holes, and the conventional method of forming via hole one by one has created the problem of taking too much time for manufacturing a device mounting board.

### SUMMARY OF THE INVENTION

One of the advantages of the present invention is to shorten the manufacturing time for a device mounting board adapted for mounting a semiconductor device and for a semiconductor module having a semiconductor device mounted on the device mounting board.

One embodiment of the present invention relates to a device mounting board. The device mounting board comprises a substrate made of a composition containing amorphous silicon; an adhesive layer provided on at least either one of two main surfaces of the substrate; a first wiring layer provided on one of the main surfaces of the substrate; a second wiring layer provided on the other main surface of the substrate; and a via conductor, which is provided in a via hole that penetrates the substrate and the adhesive layer, operative to electrically connect the first wiring layer and the second wiring layer.

One embodiment of the present invention relates to a device mounting board. The device mounting board comprises: a first substrate structural unit including a substrate made of a composition containing amorphous silicon, a first adhesive layer provided on one of the main surfaces of the substrate, and a second adhesive layer provided on the other main surface of the substrate; a first wiring layer provided on the main surface of the first adhesive layer on the opposite side from the substrate; a second wiring layer provided on the main surface of the second adhesive layer on the opposite side from the substrate; and a via conductor, which is provided in a via hole that penetrates the substrate, the first adhesive layer, and the second adhesive layer, operative to electrically connect the first wiring layer and the second wiring layer.

According to the present embodiment, the manufacturing time for a device mounting board adapted for mounting a semiconductor device and for a semiconductor module having a semiconductor device mounted on the device mounting board can be shortened.

In the above embodiment, an insulating resin layer provided on the main surface of the first substrate structural unit, a wiring layer provided on the main surface of the insulating resin layer on the opposite side from the first substrate structural unit, and a via conductor, which is provided in a via hole that penetrates the insulating resin layer, operative to electrically connect the first wiring layer or the second wiring layer with the wiring unit may be provided.

In the above embodiment, a multi-layered wiring structure may be formed by alternately laminating the first substrate structural unit and the insulating resin layer. In the above embodiment, a multi-layered wiring structure may be formed by laminating the first substrate structural units in series.

In the above embodiment, the substrate may be a glass. In the above embodiment, the first adhesive layer and the second adhesive layer may be photocurable resins.

Another embodiment of the present invention relates to a semiconductor module. The semiconductor module comprises: the device mounting board according any one of the embodiments; and a semiconductor device having a device electrode electrically connected to either the first wiring layer or the wiring unit.

Yet another embodiment of the present invention is a mobile device. The mobile device carries the semiconductor module of the above-described embodiment.

Yet another embodiment of the present invention relates to a method of manufacturing a device mounting board. A manufacturing method of the device mounting board comprises: preparing a substrate, which is made of a composition containing amorphous silicon, having a photocurable adhesive layer laminated on the main surface thereof; fixing a metal layer on the substrate by radiating a light on the adhesive layer and by laminating the metal layer on the main surface of the adhesive layer in random order; forming a plurality of via holes by selectively removing the metal layer so as to simultaneously remove the substrate and the adhesive layer in a selective manner by using a residual metal layer as a mask; electrically connecting, by forming a via conductor in the via hole, the residual metal layer and the via conductor; and forming a wiring layer by selectively removing the residual metal layer.

In forming a via hole in the above embodiment, dry etching may be performed so as to simultaneously remove the adhesive layer in a selective manner so that multiple via holes are formed.

One embodiment of the invention relates to a device mounting board. The device mounting board comprises: a second substrate structural unit including a substrate made of a composition containing amorphous silicon, a first wiring layer provided on one of the main surfaces of the substrate, and a second wiring layer provided on the other main surface of the substrate; and a via conductor, which is provided in a via hole that penetrates the substrate, operative to electrically connect the first wiring layer and the second wiring layer, wherein a plurality of the second substrate structural units are laminated and an adhesive layer is placed between the substrates of the plurality of the second substrate structural units, and the first wiring layer or the second wiring layer are, while covering the substrate, in contact with the substrate.

In the embodiment, the first wiring layer or the second wiring layer are, while covering the substrate around the via hole, in contact with the substrate. According to these embodiments, the thickness of a device mounting board adapted for mounting a semiconductor device and for a semiconductor module having a semiconductor device mounted on the device mounting board can be reduced.

In the embodiment, a multi-layered wiring structure is formed by alternately laminating the second substrate structural unit and the insulating resin layer.

Furthermore, in the embodiment, a multi-layered wiring structure is formed by laminating the second substrate structural units in series.

Also in the embodiment, the substrate is a glass.

In the above embodiment, the adhesive layer is a photocurable resin.

According to the embodiment, the adhesive layer can be hardened by way of the substrate without heating.

One embodiment of the present invention relates to a method of manufacturing a device mounting board. A manufacturing method of the device mounting board comprises: preparing a substrate made of a composition containing amorphous silicon; laminating a metal layer on the main surface of the substrate; forming a plurality of via holes by selectively removing the metal layer so as to simultaneously remove the substrate in a selective manner by using a residual metal layer as a mask; electrically connecting, by forming a via conductor in the via hole, the residual metal layer and the via conductor; and forming a wiring layer by selectively removing the residual metal layer.

According to the embodiment, a process of device mounting board can be simplified since a substrate can be simultaneously removed.

### BRIEF DESCRIPTION OF THE DRAWINGS

Embodiments will now be described, by way of example only, with reference to the accompanying drawings that are meant to be exemplary, not limiting, and wherein like elements are numbered alike in several figures, in which:

FIG. 1 is a schematic diagram showing a semiconductor module, according to the embodiment 1, mounted on a print wiring board;

FIGS. 2A-2C are sectional views showing a manufacturing method of a device mounting board and a semiconductor module;

FIGS. 3A-3C are sectional views showing a manufacturing method of a device mounting board and a semiconductor module;

FIGS. 4A-4C are sectional views showing a manufacturing method of a device mounting board and a semiconductor module;

FIGS. 5A-5C are sectional views showing a manufacturing method of a device mounting board and a semiconductor module;

FIGS. 6A-6C are sectional views showing a manufacturing method of a device mounting board and a semiconductor module;

FIG. 7 is a schematic diagram showing a semiconductor module, according to the exemplary variation of the embodiment 1, mounted on a print wiring board;

FIG. 8 is a schematic diagram showing a semiconductor module, according to the exemplary variation of the embodiment 1, mounted on a print wiring board;

FIG. 9 is a schematic diagram showing a semiconductor module, according to the exemplary variation of the embodiment 1, mounted on a print wiring board;

FIG. 10 is a schematic diagram showing a semiconductor module, according to the exemplary variation of the embodiment 1, mounted on a print wiring board;

FIG. 11 is a schematic diagram showing a semiconductor module, according to the embodiment 2, mounted on a print wiring board;

FIGS. 12A-12C are sectional views showing a manufacturing method of a device mounting board and a semiconductor module;

FIGS. 13A-13C are sectional views showing a manufacturing method of a device mounting board and a semiconductor module;

FIGS. 14A-14C are sectional views showing a manufacturing method of a device mounting board and a semiconductor module;

FIGS. 15A-15C are sectional views showing a manufacturing method of a device mounting board and a semiconductor module;

FIGS. 16A-16C are sectional views showing a manufacturing method of a device mounting board and a semiconductor module;

FIGS. 17A-17C are sectional views showing a manufacturing method of a device mounting board and a semiconductor module;

FIG. 18 is a schematic diagram showing a semiconductor module, according to the embodiment 3, mounted on a print wiring board;

FIGS. 19A-19F are sectional views showing a manufacturing method of a device mounting board and a semiconductor module;

FIGS. 20A-20B are sectional views showing a manufacturing method of a device mounting board and a semiconductor module;

FIG. 21 is a schematic diagram showing a semiconductor module, according to the exemplary variation of the embodiment 3, mounted on a print wiring board;

FIG. 22 is a schematic diagram showing a semiconductor module, according to the exemplary variation of the embodiment 3, mounted on a print wiring board;

FIG. 23 is a schematic diagram showing a semiconductor module, according to the exemplary variation of the embodiment 3, mounted on a print wiring board;

FIG. 24 is a schematic diagram showing a semiconductor module, according to the exemplary variation of the embodiment 3, mounted on a print wiring board;

FIG. 25 is a schematic diagram showing a semiconductor module, according to the embodiment 4, mounted on a print wiring board;

FIG. 26 is a diagram showing the configuration of a mobile phone according to the embodiment 3; and

FIG. 27 is a partial cross sectional view of a mobile phone.

### DETAILED DESCRIPTION OF THE INVENTION

The invention will now be described by reference to the preferred embodiments. This does not intend to limit the scope of the present invention, but to exemplify the invention.

Described below is an explanation with reference to figures, based on the preferred embodiments of the present invention. Like reference characters designate like or corresponding elements, members and processes throughout the views. The description of them will not be repeated for brevity. Reference herein to details of the illustrated embodiments is not intended to limit the scope of the claims. It should be understood that not all of the features or the combination thereof discussed are essential to the invention.

### Embodiment 1

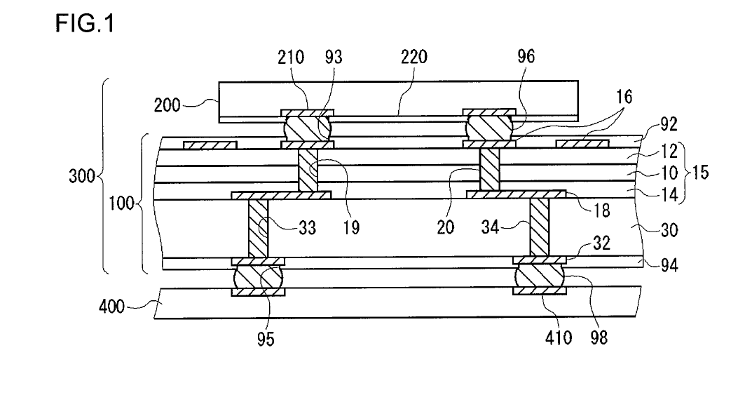

FIG. 1 is a schematic diagram showing a semiconductor module 300, according to the embodiment 1, mounted on a print wiring board 400. The semiconductor module 300 is provided with a device mounting board 100 and a semiconductor device 200 mounted on the device mounting board 100.

The device mounting board 100 is provided with a substrate 10, a first adhesive layer 12 provided on one of the main surfaces of the substrate 10, and a second adhesive layer 14 provided on the other main surface of the substrate 10. A substrate structural unit 15 (first substrate structural unit) is formed by the substrate 10, the first adhesive layer 12, and the second adhesive layer 14. The device mounting board 100 is provided with a first wiring layer 16 provided on the main surface of the first adhesive layer 12 on the opposite side from the substrate 10 and with a second wiring layer 18 provided on the main surface of the second adhesive layer 14 on the opposite side from the substrate 10. The device mounting board 100 is provided with a via conductor 20, which is provided in a via hole 19 penetrating the substrate 10, the first adhesive layer 12, and the second adhesive layer 14, that electrically connects the first wiring layer 16 and the second wiring layer 18.

The substrate 10 is made of an amorphous composition containing silicon (Si containing composition) and is, for example, a glass consisting primarily of silicon dioxide (SiO₂). It exhibits high material uniformity compared to a normal resin, for example, a resin containing fibers and fillers. Therefore, dry etching can be easily performed. Thus, in forming the via hole 19 on the substrate 10, dry etching, in addition to a drilling process or a laser process, can be selected. The employment of a dry etching technique, different from that of a drilling process or laser process where via holes 19 are formed one by one, allows for the formation of multiple via holes 19 at a time on the substrate 10. Furthermore, compared to an insulating resin layer 30 that will be described hereinafter, the substrate 10 has a coefficient of thermal expansion closer to the coefficient of thermal expansion of a semiconductor device 200 containing a silicon wafer (Si wafer). Therefore, a failure in an electrical connection due to warpage can be prevented when mounting a semiconductor chip on a device mounting board consisting of a glass substrate.

The first adhesive layer 12 and the second adhesive layer 14 comprise, for example, photocurable resins. The photocurable resin is, for example, a UV-curable resin. Specifically, the first adhesive layer 12 and the second adhesive layer 14 comprise, for example, a photopolymerizable prepolymer (oligonomer), a photopolymerizable diluent (monomer), and the like. A photopolymerizable prepolymer includes, for example, ether acrylate, urethane acrylate, epoxy acrylate, melamine acrylate, acrylic resin acrylate, unsaturated polyester, and the like. A photopolymerizable diluent includes, for example, 2-ethylhexyl acrylate, polyethylene glycol diacrylate, dipentaerythritol hexa-acrylate, vinyl cyclohexene monoxide, cyclohexanedimethanol divinyl ether, and the like.

The first wiring layer 16 and the second wiring layer 18 are formed by a conductive material, preferably a metal such as copper. It may be also formed by electrolytic copper. At the end area of the first wiring layer 16, a land area is formed for wiring and for the placement of a solder ball 96 described hereinafter that is to be placed on the surface opposite from the first adhesive layer 12.

The via conductor 20 is provided in the via hole 19 that penetrates the substrate 10, the first adhesive layer 12, and the second adhesive layer 14 at a predetermined position. In this embodiment, the via conductor 20 is formed so as to fill in the via hole 19. The via conductor 20 is made of a conductive material and preferably of the same material used for the first wiring layer 16 and the second wiring layer 18.

The device mounting board 100 of the embodiment is further provided with an insulating resin layer 30, which is provided on the main surface of the substrate structural unit 15, and with a wiring unit 32, which is provided on the main surface of the insulating resin layer 30 opposite from the substrate structural unit 15. The device mounting board 100 is provided with a via conductor 34, which is provided in a via hole 33 that penetrates the insulating resin layer 30, that electrically connects the first wiring layer 16 or second wiring layer 18 with the wiring unit 32. In this embodiment, the insulating resin layer 30 is laminated on the main surface of the substrate structural unit 15 on the side of the second adhesive layer 14, and the second wiring layer 18 and the wiring unit 32 are electrically connected by way of the via conductor 34.

The insulating resin layer 30 includes a thermosetting resin, for example, a melamine derivative such as a BT resin, a liquid crystal polymer, an epoxy resin, a PPE resin, a polyimide resin, a fluorocarbon resin, a phenol resin, a polyamide bis-maleimide, and the like. The insulating resin layer 30 may include a glass fiber, an aramide non-woven fabric, and an alumina filler. The wiring unit 32 and the via conductor 34 have the same structures as those of the above-stated first wiring layer 16 and second wiring layer 18 and of the via conductor 20, respectively.

On the main surface of the first wiring layer 16 opposite from the first adhesive layer 12 and on the main surface of the wiring unit 32 opposite from the insulating resin layer 30, a protection layer 92 and a protection layer 94 are provided for the prevention of oxidation, etc., of the first wiring layer 16 and the wiring unit 32, respectively. The protection layers 92 and 94 include a solder resist layer and the like. In the predetermined areas of the protection layer 92 and the protection layer 94 that correspond to the land areas of the first wiring layer 16 and the wiring unit 32, an opening 93 and an opening 95 are formed, respectively. The land areas of the first wiring layer 16 and the wiring unit 32 are exposed through the openings 93 and 95. Solder balls 96 and 98 used as electrodes for external connection are formed in the openings 93 and 95, and the solder ball 96 and the solder ball 98 are electrically connected to the first wiring layer 16 and the wiring unit 32, respectively. The positions in which the solder balls 96 and 98 are formed, in other words, the forming areas of the openings 93 and 95 are, for example, the end areas where the wiring is extended by rewiring. In the embodiment, the solder balls 96 and 98 are provided as electrodes for external connection. Alternatively, the connection to the semiconductor device 200 and to the print wiring board 400 may be achieved by wire bonding, etc.

The semiconductor module 300 is formed with the semiconductor device 200 mounted on the device mounting board 100 having the above-mentioned structure. The semiconductor module 300 of the embodiment is provided with the semiconductor device 200 located on the side of the substrate structural unit 15 of the device mounting board 100, where the first wiring layer 16 and a device electrode 210 of the semiconductor device 200 are electrically connected by way of the solder ball 96.

The semiconductor device 200 has the device electrode 210 at the position opposite to the opening 93 of the first wiring layer 16. On the main surface of the semiconductor device 200 on the side where the device electrode 210 is provided, an insulating film (not shown) such as a silicon oxide film is provided. Furthermore, on the main surface of the semiconductor device 200, which is on the insulating film, on the side of the substrate structural unit 15, a device protection layer 220 such as a polyimide layer, where an opening is provided so that the device electrode 210 is exposed, is laminated. The specific examples of the semiconductor device 200 include a semiconductor chip such as an integrated circuit (IC), a large-scale integrated circuit (LSI), and the like. For example, aluminum (Al) is used for the device electrode 210.

The semiconductor device 200 is placed on the device mounting board 100 on the side of the substrate structural unit 15, and the semiconductor module 300 in which the first wiring layer 16 and the device protection layer 220 are electrically connected is placed so that the print wiring board 400 is placed on the side of the insulating resin layer 30. The wiring unit 32 and a board electrode 410 of the print wiring board 400 are electrically connected by way of the solder ball 98. This allows the semiconductor device 200 to be mounted on the print wiring board 400 by way of the device mounting board 100.

(The Manufacturing Method of a Device Mounting Board and a Semiconductor Module)

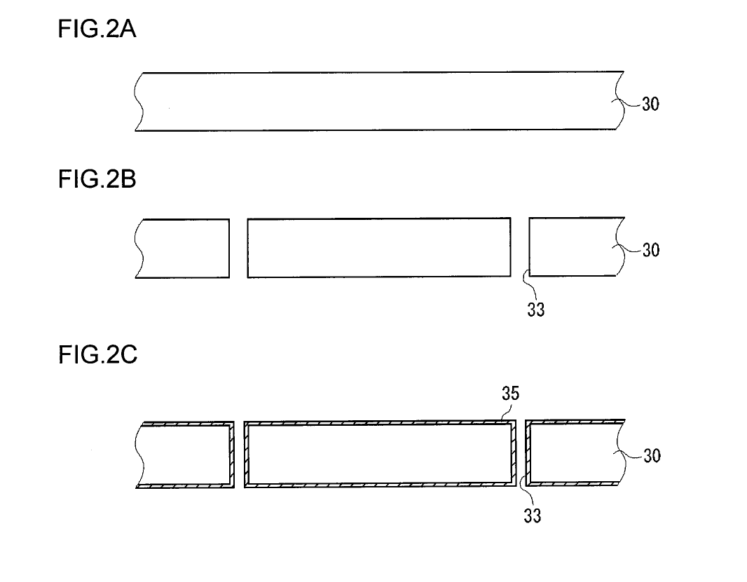

FIGS. 2A-2C, FIGS. 3A-3C, FIGS. 4A-4C, FIGS. 5A-5C, and FIGS. 6A-6C are sectional views showing a manufacturing method of the device mounting board 100 and the semiconductor module 300.

As shown in FIG. 2A, the insulating resin layer 30 is prepared first.

As shown in FIG. 2B, the via hole 33 is then formed by performing, for example, a laser process on a predetermined position of the insulating resin layer 30. In the laser process, for example, a slab RF-excited CO₂ laser (wavelength 10.6 μm, pulse width 15 μsec) is used to form the via hole 33 by irradiating a predetermined position of the insulating resin layer 30 with a laser beam focused to have a diameter of about 100 μm.

As shown in FIG. 2C, a seed layer 35 made of a copper thin film having a thickness of a couple hundred nm is precipitated on the surface of the insulating resin layer 30 including the sidewall surface of the via hole 33 by, for example, electroless plating of copper using palladium and the like as a catalyst.

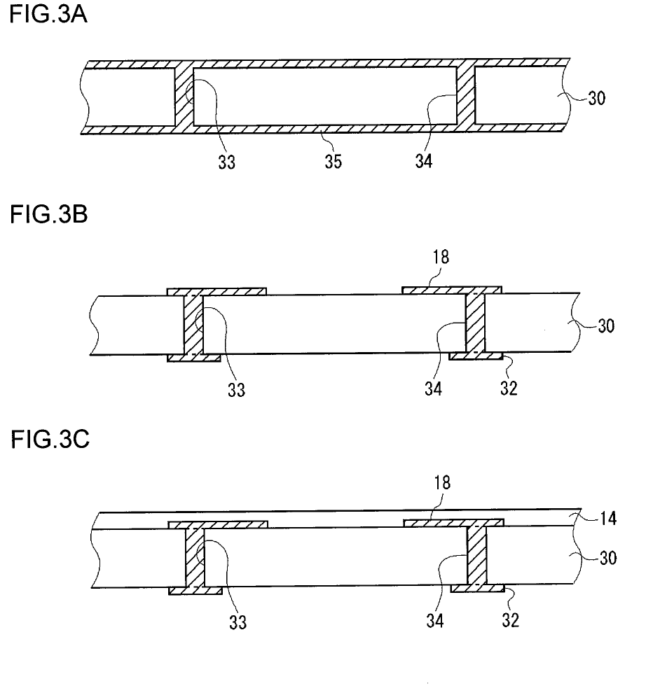

As shown in FIG. 3A, the via conductor 34 is formed by, for example, electrolytic copper plating using a copper sulfate solution as a plating solution. By this electrolytic copper plating, copper is deposited on the surface of the seed layer 35, and the seed layer 35 is thickened to achieve a predetermined thickness.

A resist (not shown) is then selectively formed by a photolithography process in accordance with the patterns of the second wiring layer 18 and the wiring unit 32. More specifically, a resist film having a predetermined thickness is pasted on the thickened seed layer 35 by using a laminating device, then exposed by using a photomask having the patterns of the second wiring layer 18 and the wiring unit 32, and then developed so as to selectively form a resist on the thickened seed layer 35. In order to improve the closeness of contact with the resist, pretreatment such as grinding and washing is desirably performed on the surface of the thickened seed layer 35 before the lamination of a resist film. As shown in FIG. 3B, the second wiring layer 18 and the wiring unit 32 that have predetermined patterns on the insulating resin layer 30 are formed by performing etching on the thickened seed layer 35 by using the resist as a mask.

As shown in FIG. 3C, the second adhesive layer 14 is then laminated on the main surface of the insulating resin layer 30 on the side where the second wiring layer 18 is formed.

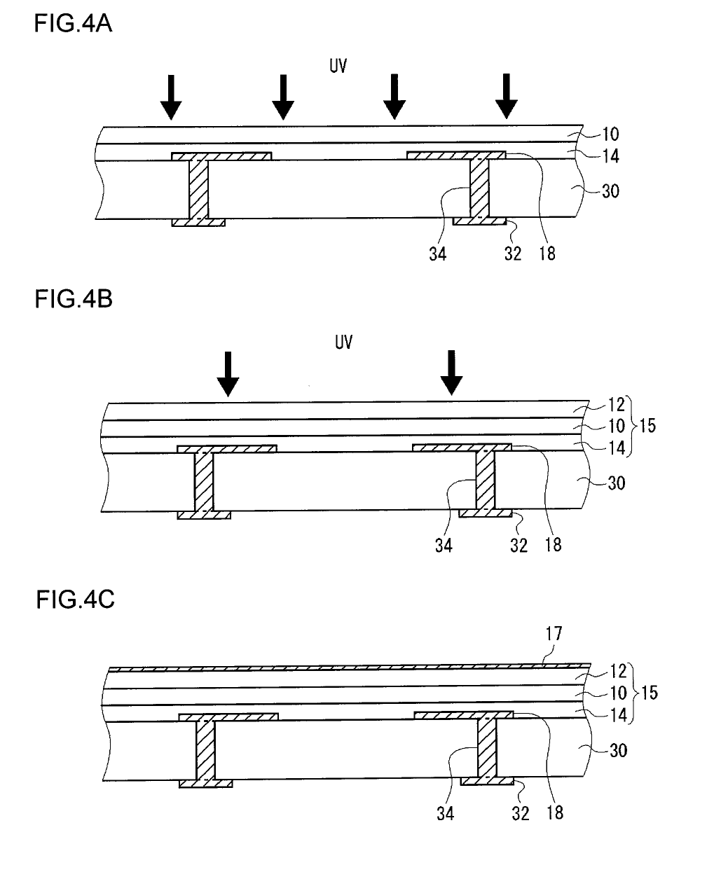

As shown in FIG. 4A, the substrate 10 is then laminated on the main surface of the second adhesive layer 14 on the opposite side from the insulating resin layer 30. A UV ray (ultraviolet ray) is radiated on the side where the substrate 10 is laminated. The substrate 10 is a glass and transmits a UV ray. Thus, a UV ray radiated on the substrate 10 side passes through the substrate 10 and reaches the second adhesive layer 14, thus hardening the second adhesive layer 14. This allows the substrate 10 to be fixed to the insulating resin layer 30 through the second adhesive layer 14. Since the second adhesive layer 14 is hardened by the radiation of a UV ray, problems that can be caused in thermal hardening such as peeling of the second wiring layer 18 or the wiring unit 32 from the insulating resin layer 30 due to differences in coefficient of thermal expansion can be prevented.

As shown in FIG. 4B, the first adhesive layer 12 is then laminated on the main surface of the substrate 10 on the opposite side from the second adhesive layer 14. With this, the substrate 10 is prepared, being made of a composition containing amorphous silicon and having a photocurable adhesive layer, that is, the first adhesive layer 12 is laminated on its main surface. A predetermined amount of a UV ray (the intensity is weaker than that of the ray radiated on the second adhesive layer 14) is radiated on the first adhesive layer 12 so as to semi-harden the first adhesive layer 12.

As shown in FIG. 4C, a copper thin film 17 is laminated on the main surface of the semi-hardened first adhesive layer 12 on the opposite side from the substrate 10 as a metal layer. Heat is applied to this so as to completely harden the first adhesive layer 12, fixing the copper thin film 17 to the substrate 10 by way of the first adhesive layer 12. In this case, only a little amount of heating is required since the first adhesive layer 12 is in a semi-hardened state. Thus, the likelihood of peeling of the second wiring layer 18 or the wiring unit 32 from the insulating resin layer 30 due to differences in coefficient of thermal expansion can be reduced.

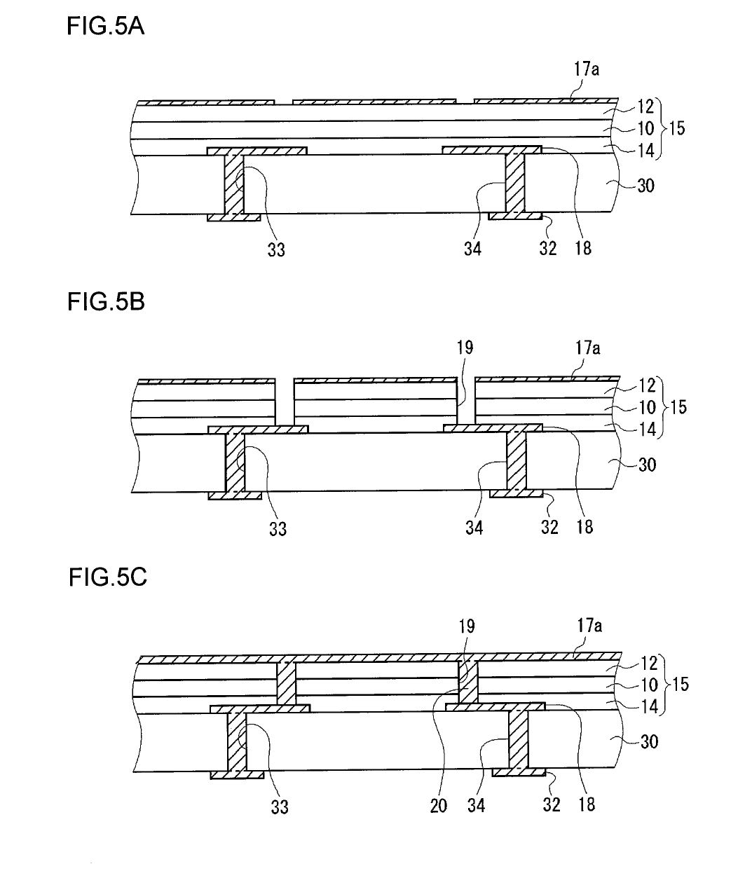

As shown in FIG. 5A, patterning is performed on the copper thin film 17 by a photolithography process and an etching process so as to form a residual copper thin film 17a having a predetermined pattern on the first adhesive layer 12.

As shown in FIG. 5B, dry etching is performed by using the residual copper thin film 17a having a predetermined pattern as a mask so as to simultaneously remove the first adhesive layer 12, the substrate 10, and the second adhesive layer 14 in a selective manner so that multiple via holes 19 are formed. In the embodiment, the substrate 10 is made of a glass and thus is thinner than the insulating resin layer 30. Therefore, dry etching can be employed. Dry etching can be performed by, for example, a plasma etching method. When forming the via hole 19 by a plasma etching method, the etching process is performed by supplying a gas having a flow rate of HBr/O₂: 50/4 sccm while the pressure inside the chamber is kept at 2 mTorr under the condition where a microwave is at 1800 w and where a bias high-frequency wave is at 20 w.

As shown in FIG. 5C, the via conductor 20 is then formed in the via hole 19 by an electroless plating process and an electroplating process. By this process, copper is deposited on the surface of the residual copper thin film 17a, and the residual copper thin film 17a is thickened to achieve a predetermined thickness. The via conductor 20 and the residual copper thin film 17a are electrically connected.

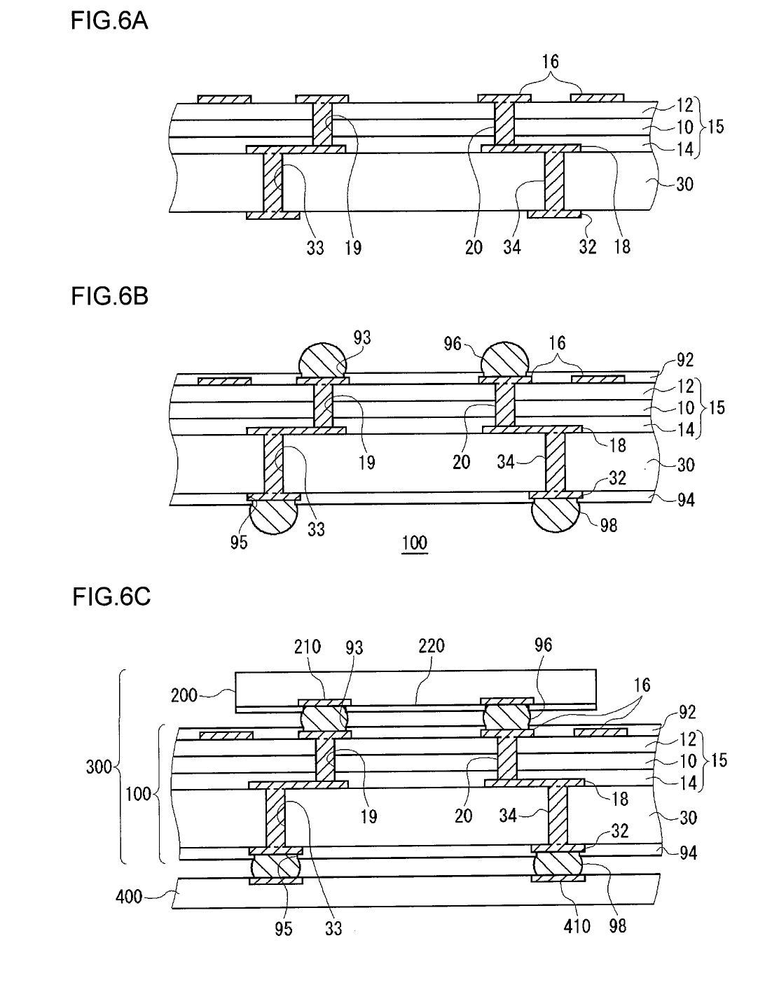

As shown in FIG. 6A, patterning is performed on the residual copper thin film 17a by a photolithography process and an etching process so as to form the first wiring layer 16 having a predetermined wiring pattern on the first adhesive layer 12.

As shown in FIG. 6B, the protection layer 92 and the protection layer 94, which have an opening 93 and an opening 95 in areas corresponding to the positions at which the solder balls 96 and 98 are formed, are formed on the main surface of the first adhesive layer 12 on the side of the first wiring layer 16 and on the main surface of the insulating resin layer 30 on the side of the wiring unit 32. The solder balls 96 and 98 are formed in the openings 93 and 95. In this manner, the device mounting board 100 is formed. The device mounting board 100 may not includes the protection layers 92 and 94 or the solder balls 96 and 98.

As shown in FIG. 6C, the semiconductor module 300 is formed by placing on the side of the substrate structural unit 15 of the device mounting board 100 the semiconductor device 200 having the device electrode 210 and the device protection layer 220 and by electrically connecting the first wiring layer 16 and the device electrode 210 of the semiconductor device 200 through the solder ball 96. The semiconductor module 300 is mounted on the print wiring board 400 by placing the print wiring board 400 on the side of the insulating resin layer 30 of the semiconductor module 300 and by electrically connecting the wiring unit 32 and the board electrode 410 of the print wiring board 400 through the solder ball 98.

The thickness of the substrate 10, the first adhesive layer 12, the second adhesive layer 14, the first wiring layer 16, the second wiring layer 18, and the wiring unit 32 of the embodiment are, for example, about 100-700 μm, about 20-30 μm, about 20-30 μm, about 15-25 μm, about 15-25 μm, and about 15-25 μm, respectively. The diameters of the via conductor 20 and the via conductor 34 are, for example, about 50-700 μmφ and about 90-150 μmφ, respectively.

To summarize the functional effects obtained by the above-explained structure, the device mounting board 100 and the semiconductor module 300 of the embodiment are provided with the substrate structural unit 15 including the substrate made of a composition containing amorphous silicon, the first adhesive layer 12, and the second adhesive layer 14. The first wiring layer 16 is provided on the main surface of the first adhesive layer 12, and the second wiring layer 18 is provided on the main surface of the second adhesive layer 14. The first wiring layer 16 and the second wiring layer 18 are electrically connected by the way of the via conductor 20 provided in the via hole that penetrates the substrate 10, the first adhesive layer 12, and the second adhesive layer 14. As described above, the substrate 10 is made of a composition containing amorphous silicon, for example, a glass consisting chiefly of SiO₂ in the embodiment. Since it exhibits high material uniformity compared to a normal resin, for example, a resin containing fibers and fillers, dry etching can be easily performed. Thus, in forming the via hole 19 on the substrate 10, dry etching can be selected. As a result, multiple via holes 19 can be formed simultaneously, and the manufacturing time of the device mounting board 100 and the semiconductor module 300 can thus be shortened. Further increase in the future of the number of via holes to be formed allows the device mounting board 100 of the embodiment to achieve more effects. Also, a via hole with less taper can be formed with high positional accuracy by dry etching, and narrow-pitch via holes 19 formed on the substrate 10 can thus be obtained.

While a conventional resin layer contains, for example, glass fibers to provide certain stiffness, the substrate 10 has a composition containing silicon approximately uniform across the substrate. Thus, when the via hole 19 that penetrates the substrate 10, a via hole 19 that has a more uniform internal diameter can be formed. Thus, with regard to a via hole 19 that is formed on the substrate 10, the diameter and the pitch can be further decreased. The substrate 10 allows the electrical reliability between the first wiring layer 16 and the second wiring layer 18 to be improved since there is a small variation in the dielectric constant thereof.

The device mounting board 100 of the embodiment is further provided with an insulating resin layer 30, which is provided on the main surface of the substrate structural unit 15, and with a wiring unit 32, which is provided on the main surface of the insulating resin layer 30 opposite from the substrate structural unit 15. A via conductor 34 is provided in the via hole 33 that penetrates the insulating resin layer 30, and the wiring layer of the substrate structural unit 15 and the wiring unit 32 are electrically connected. The semiconductor device 200 is placed on the side of the substrate 10 where the difference in the coefficient of thermal expansion of the semiconductor device 200 is smaller than that of the insulating resin layer 30, and the print wiring board 400 is placed on the side of the insulating resin layer 30 where the difference in the coefficient of thermal expansion of the print wiring board 400 is smaller than that of the substrate 10. The semiconductor device 200 and the print wiring board 400 are electrically connected. Therefore, the thermal stress, for example, due to the thermal process caused when the semiconductor module 300 is mounted on the print wiring board 400 or due to a temperature change in the usage environment of an electronic device carrying the semiconductor module 300 can be reduced. Thus, the reliability of the connection between the semiconductor device 200 and the print wiring board 400 can be improved. This allows the reliability between the semiconductor module 300 and the electronic device on which the semiconductor module is mounted to be improved.

Since a photocurable resin is used as an adhesive layer, the amount of heat applied at the time of manufacturing the device mounting board 100 can be reduced. With this, warpage and the like of the device mounting board 100 due to the difference in the coefficient of thermal expansion among a substrate, a wiring layer, and an insulating resin layer at the time of manufacturing the device mounting board 100 can be prevented, and the reliability of the connection of the device mounting board 100 is improved.

(Exemplary Variation)

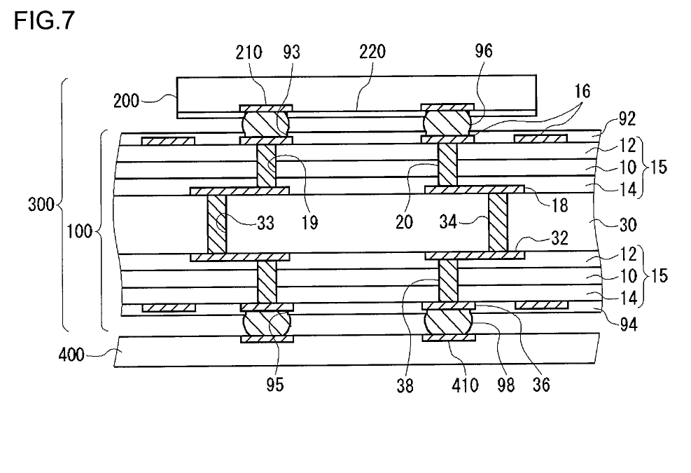

FIGS. 7, 8, 9, and 10 are schematic diagrams illustrating the semiconductor module 300 according to the exemplary variation of the embodiment 1 that is mounted on the print wiring board 400. As shown in FIGS. 7-10, the device mounting board 100 can have a multi-layered wiring structure in which the substrate structural unit 15 and the insulating resin layer 30 are alternately laminated while a wiring layer is sandwiched between them. The other aspects are the same as the corresponding aspects of the embodiment 1.

The device mounting board 100 according to the embodiment includes a first exemplary variation shown in FIG. 7. In other words, it is a structure where a second substrate structural unit 15 is laminated on the main surface of the insulating resin layer 30 on the side of the wiring unit 32 in the device mounting board 100 of the embodiment 1 and where the wiring layer 36 is formed on the main surface of the second substrate structural unit 15 on the opposite side of the insulating resin layer 30. The wiring unit 32 and the wiring layer 36 are electrically connected by way of the via conductor 38.

This structure allows the difference in the coefficient of thermal expansion between the semiconductor device 200 and the device mounting board 100 to be reduced and also allows the warpage of the device mounting board 100 to be prevented since the device mounting board 100 is sandwiched by the substrate structural units 15 on both sides.

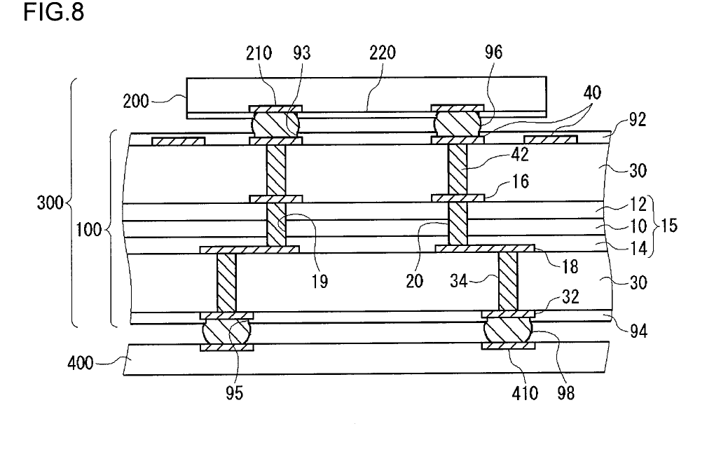

The device mounting board 100 according to the embodiment includes a second exemplary variation shown in FIG. 8. In other words, it is a structure where a second insulating resin layer 30 is laminated on the main surface of the first adhesive layer 12 on the side of the first wiring layer 16 in the device mounting board 100 of the embodiment 1 and where the wiring layer 40 is formed on the main surface of the second insulating resin layer 30 on the opposite side from the first adhesive layer 12. The first wiring layer 16 and the wiring layer 40 are electrically connected by way of the via conductor 42.

This structure allows the difference in the coefficient of thermal expansion between the device mounting board 100 and the print wiring board 400 to be reduced. Provided with the substrate structural units 15, it also allows a number of minute via holes to be formed at high throughput.

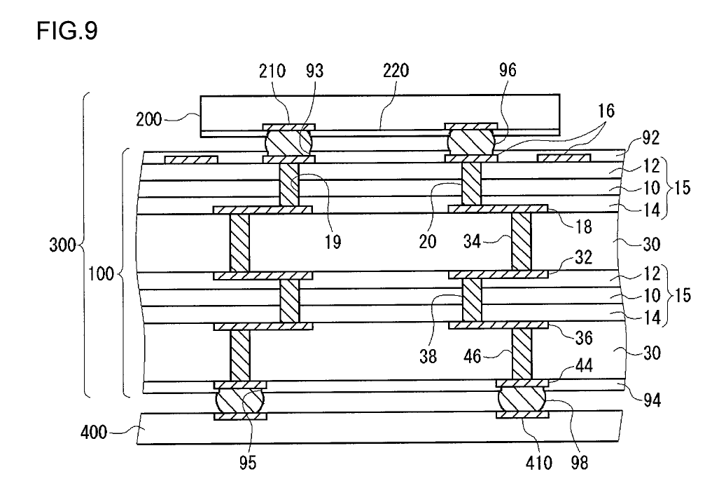

The device mounting board 100 according to the embodiment includes a third exemplary variation shown in FIG. 9. In other words, it is a structure where a second insulating resin layer 30 is laminated on the main surface of the second substrate structural units 15 on the side of the wiring layer 36 in the device mounting board 100 of the first exemplary variation shown in FIG. 7 and where the wiring layer 44 is formed on the main surface of the second insulating resin layer 30 on the opposite side of the second substrate structural units 15. The wiring layer 36 and the wiring layer 44 are electrically connected by way of a via conductor 46.

This structure allows both the difference in the coefficient of thermal expansion between the semiconductor device 200 and the device mounting board 100 and the difference in the coefficient of thermal expansion between the device mounting board 100 and the print wiring board 400 to be reduced. Provided with the substrate structural units 15, it also allows a number of minute via holes to be formed at high throughput.

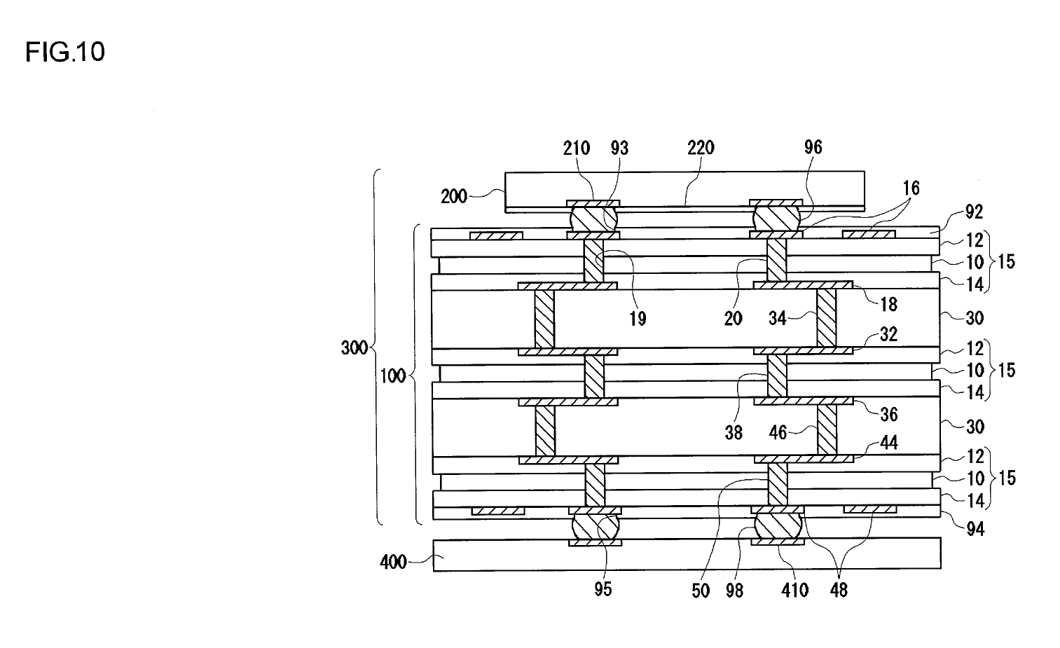

The device mounting board 100 according to the embodiment includes a fourth exemplary variation shown in FIG. 10. In other words, it is a structure where a third substrate structural unit 15 is laminated on the main surface of the second insulating resin layer 30 on the side of the wiring layer 44 in the device mounting board 100 of the third exemplary variation shown in FIG. 9 and where the wiring layer 48 is formed on the main surface of the third substrate structural unit 15 on the opposite side from the second insulating resin layer 30. The wiring layer 44 and the wiring layer 48 are electrically connected by way of a via conductor 50.

This structure allows the difference in the coefficient of thermal expansion between the semiconductor device 200 and the device mounting board 100 to be reduced and also allows the warpage of the device mounting board 100 to be prevented since the device mounting board 100 is sandwiched by the substrate structural units 15 on both sides. Provided with the substrate structural units 15, it also allows a number of minute via holes to be formed at high throughput.

### Embodiment 2

The device mounting board 100 according to the embodiment 2 differs from the one according to the embodiment 1 in that the device mounting board 100 has a multi-layered wiring structure where the substrate structural units 15 are laminated in series. The embodiment is described in detail in the following. The other parts of the structure of the device mounting board 100 and the structures of the semiconductor device 200 and the print wiring board 400 are basically the same as that of the embodiment 1. Like numerals represent like constituting elements in the embodiment 1, and the description thereof is appropriately omitted.

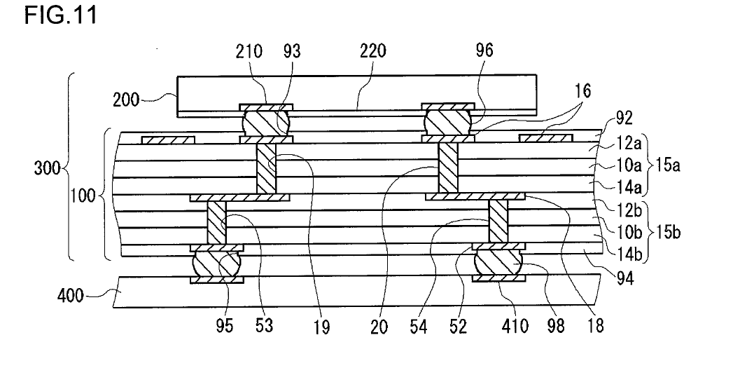

FIG. 11 is a schematic diagram illustrating the semiconductor module 300 according to the embodiment 2 that is mounted on the print wiring board 400. The semiconductor module 300 is provided with the device mounting board 100 and with the semiconductor device 200 mounted on the device mounting board 100.

The device mounting board 100 is provided with a substrate structural unit 15a comprising a substrate 10a, a first adhesive layer 12a provided on one of the main surfaces of the substrate 10a, and a second adhesive layer 14a provided on the other main surface of the substrate 10a. The device mounting board 100 is provided with the first wiring layer 16 provided on the main surface of the first adhesive layer 12a on the opposite side from the substrate 10a and with the second wiring layer 18 provided on the main surface of the second adhesive layer 14a on the opposite side from the substrate 10a. The device mounting board 100 is provided with a via conductor 20, which is provided in the via hole 19 that penetrates the substrate 10a, the first adhesive layer 12a, and the second adhesive layer 14a, that electrically connects the first wiring layer 16 and the second wiring layer 18.

The substrate 10 is made of a composition containing amorphous silicon, for example, a glass consisting chiefly of SiO₂. Therefore, the substrate 10 has higher stiffness compared to a normal resin. Thus, the thickness thereof can be reduced. Thus, in forming the via hole 19 on the substrate 10, dry etching can be selected. Furthermore, compared to the insulating resin layer 30, the substrate 10 has a coefficient of thermal expansion closer to the coefficient of thermal expansion of the semiconductor device 200.

The first adhesive layer 12 and the second adhesive layer 14 comprise, for example, photocurable resins. The photocurable resin is, for example, a UV-curable resin. The first wiring layer 16 and the second wiring layer 18 are formed by a conductive material, preferably a metal such as copper. The via conductor 20 is provided in the via hole 19 that penetrates the substrate 10, the first adhesive layer 12, and the second adhesive layer 14 at a predetermined position. The via conductor 20 is made of a conductive material and preferably of the same material used for the first wiring layer 16 and the second wiring layer 18.

In the device mounting board 100 according to the embodiment, the substrate structural units 15b are laminated in series. In other words, a first adhesive layer 12b is laminated on the main surface of a second adhesive layer 14a on the side of the second wiring layer 18, and a substrate 10b is laminated on the main surface of the first adhesive layer 12b on the opposite side from the second adhesive layer 14a, and a second adhesive layer 14b is laminated on the main surface of the substrate 10b on the opposite side from the first adhesive layer 12b. A wiring layer 52 is formed on the main surface of the second adhesive layer 14b on the opposite side from the substrate 10b, and the second wiring layer 18 and the wiring layer 52 are electrically connected by way of a via conductor 54 provided in a via hole 53. The wiring layer 52 and the via conductor 54 have structures similar to those of the above-stated first wiring layer 16 and second wiring layer 18 and of the via conductor 20, respectively.

On the main surface of the first wiring layer 16 opposite from the first adhesive layer 12a and on the main surface of the wiring layer 52 opposite from the second adhesive layer 14b, the protection layer 92 and the protection layer 94 are provided for the prevention of oxidation, etc. of the first wiring layer 16 and the wiring layer 52, respectively. In the predetermined areas of the protection layer 92 and the protection layer 94, the opening 93 and the opening 95 are formed, respectively. The solder balls 96 and 98 are formed in the openings 93 and 95 as electrodes for external connection. The solder ball 96 and the solder ball 98 are electrically connected to the first wiring layer 16 and the wiring layer 52, respectively.

The device mounting board 100 having the above-stated structure and the semiconductor device 200 are electrically connected by way of the solder ball 96, and the device mounting board 100 and the print wiring board 400 are electrically connected by way of the solder ball 98. This allows the semiconductor device 200 to be mounted on the print wiring board 400 via the device mounting board 100.

(The Manufacturing Method of a Device Mounting Board and a Semiconductor Module)

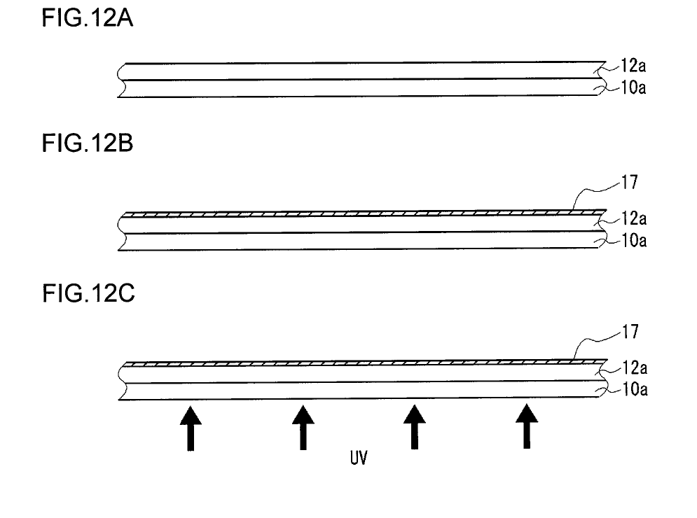

FIGS. 12A-12C, FIGS. 13A-13C, FIGS. 14A-14C, FIGS. 15A-15C, FIGS. 16A-16C, and FIGS. 17A-17C are sectional views showing a manufacturing method of the device mounting board 100 and the semiconductor module 300. As shown in FIG. 12A, the substrate 10a is prepared with the first adhesive layer 12a laminated on the main surface thereof.

As shown in FIG. 12B, the copper thin film 17 is laminated as a metal layer on the main surface of the first adhesive layer 12a on the opposite side from the substrate 10a.

As shown in FIG. 12C, the side of the substrate 10a is irradiated with a UV ray. The substrate 10a is a glass and transmits a UV ray. Thus, a UV ray irradiating the substrate 10a side passes through the substrate 10a and reaches the first adhesive layer 12a, thus hardening the first adhesive layer 12a. This allows the copper thin film 17 to be fixed to the substrate 10a through the first adhesive layer 12a.

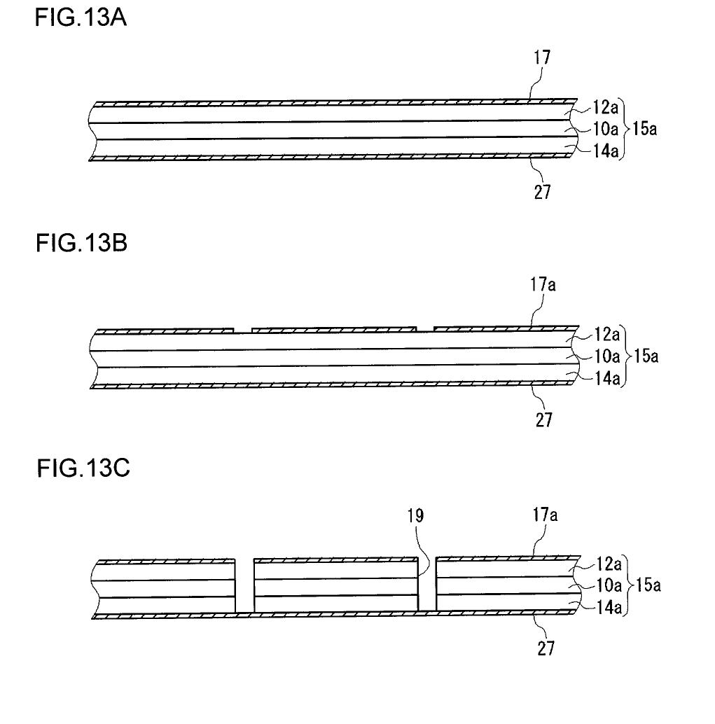

A structure as shown in FIG. 13A where a copper thin film 27 is fixed to the substrate 10a is obtained as follows. The second adhesive layer 14a is laminated on the substrate 10a on the opposite side from the first adhesive layer 12a. A predetermined amount of a UV ray is then radiated on the second adhesive layer 14a so as to semi-harden the second adhesive layer 14a, followed by the lamination of the copper thin film 27. The second adhesive layer 14 is then completely hardened by heating.

As shown in FIG. 13B, patterning is performed on the copper thin film 17 by a photolithography process and an etching process so as to form the residual copper thin film 17a having a predetermined pattern on the first adhesive layer 12a.

As shown in FIG. 13C, dry etching is performed by using the residual copper thin film 17a as a mask so as to simultaneously remove the first adhesive layer 12a, the substrate 10a, and the second adhesive layer 14a in a selective manner so that multiple via holes 19 are formed. Dry etching can be performed by, for example, a plasma etching method. When forming the via hole 19 by a plasma etching method, the etching process is performed by supplying a gas having a flow rate of HBr/O₂: 50/4 sccm while the pressure inside the chamber is kept at 2 mTorr under the condition where a microwave is at 1800 w and where a bias high-frequency wave is at 20 w.

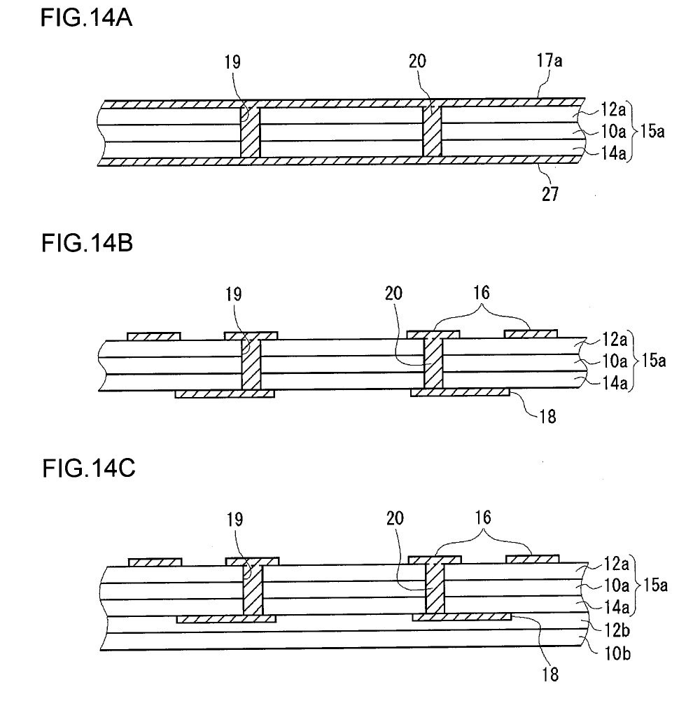

As shown in FIG. 14A, the via conductor 20 is then formed in the via hole 19 by an electroless plating process and an electroplating process. By this process, copper is deposited on the surfaces of the residual copper thin film 17a and the copper thin film 27, and the residual copper thin film 17a and the copper thin film 27 are thickened to achieve a predetermined thickness. The via conductor 20, the residual copper thin film 17a, and the copper thin film 27 are electrically connected.

As shown in FIG. 14B, patterning is performed on the residual copper thin film 17a and on the copper thin film 27 by a photolithography process and an etching process so as to form the wiring layer 16 and the second wiring layer 18 on the first adhesive layer 12a and the second adhesive layer 14a, respectively.

As shown in FIG. 14C, the first adhesive layer 12b is laminated on the main surface of the second adhesive layer 14a on the side of the second wiring layer 18, and the substrate 10b is laminated on the main surface of the first adhesive layer 12b on the opposite side from the second adhesive layer 14a.

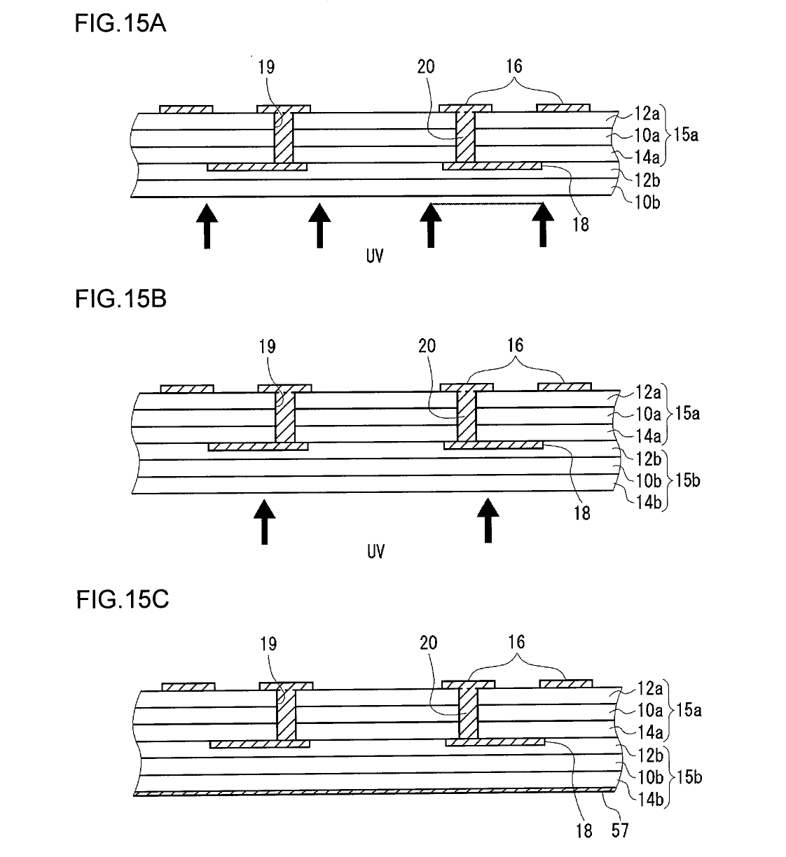

As shown in FIG. 15A, the substrate 10b is fixed to the substrate structural unit 15a through the first adhesive layer 12b by radiating a UV ray on the side of the substrate 10b so as to harden the first adhesive layer 12b.

As shown in FIG. 15B, the second adhesive layer 14b is laminated on the main surface of the substrate 10b on the opposite side from the first adhesive layer 12b, and a predetermined amount of a UV ray is radiated on the second adhesive layer 14b so as to semi-harden the second adhesive layer 14b.

As shown in FIG. 15C, the copper thin film 57 is fixed to the substrate 10b through the second adhesive layer 14b by laminating the copper thin film 57 on the semi-hardened second adhesive layer 14b, followed by completely hardening the second adhesive layer 14b by heating.

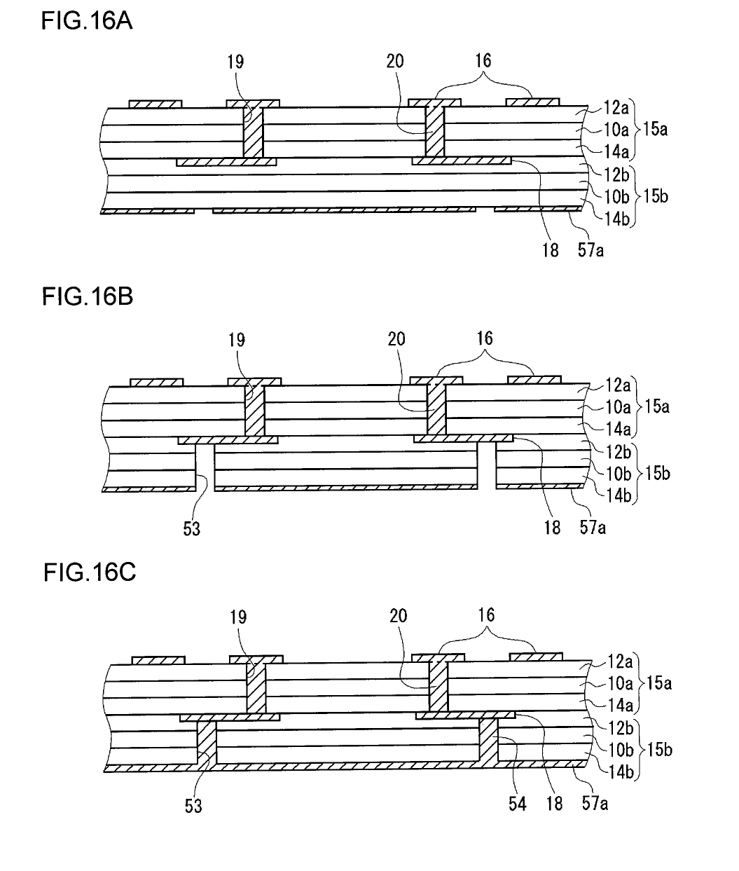

As shown in FIG. 16A, patterning is performed on the copper thin film 57 by a photolithography process and an etching process so as to form a residual copper thin film 57a having a predetermined pattern on the second adhesive layer 14b.

As shown in FIG. 16B, dry etching is performed by using the residual copper thin film 57a as a mask so as to simultaneously remove the second adhesive layer 14b, the substrate 10b, and the first adhesive layer 12b in a selective manner so that multiple via holes 53 are formed.

As shown in FIG. 16C, the via conductor 54 is then formed in the via hole 53 by an electroless plating process and an electroplating process. By this process, copper is deposited on the surface of the residual copper thin film 57a, and the residual copper thin film 57a is thickened to achieve a predetermined thickness. The via conductor 54 and the residual copper thin film 57a are electrically connected.

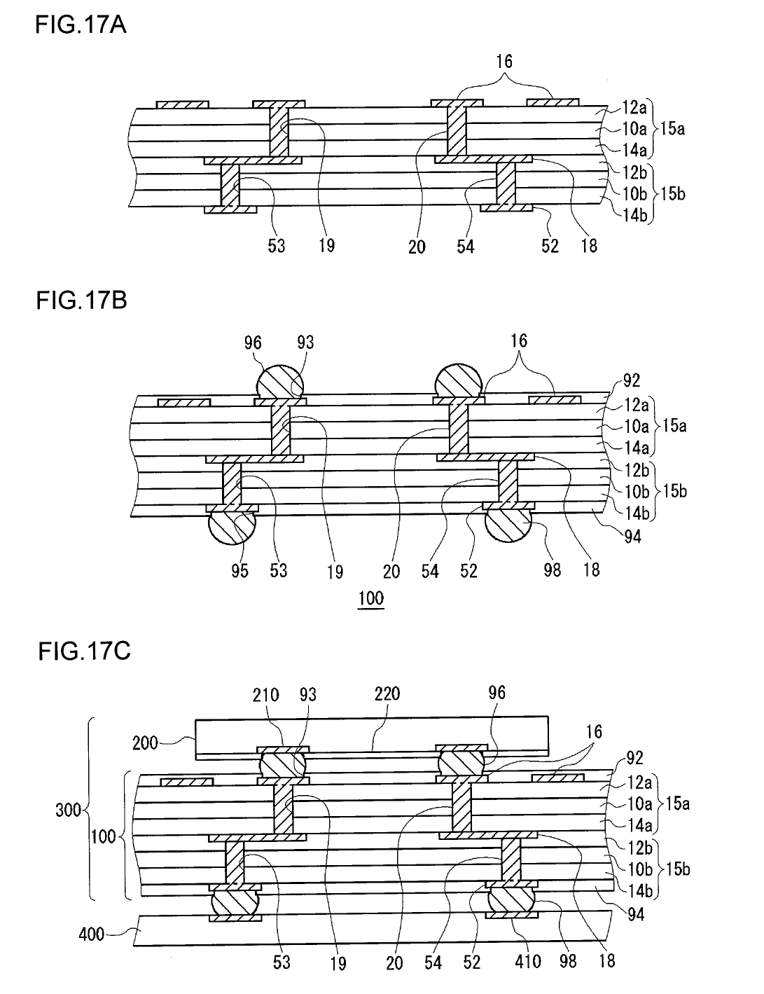

As shown in FIG. 17A, patterning is performed on the residual copper thin film 57a by a photolithography process and an etching process so as to form the wiring layer 52 on the second adhesive layer 14b.

As shown in FIG. 17B, the protection layer 92 and the protection layer 94, which have the opening 93 and the opening 95 in areas correspond to the positions at which the solder balls 96 and 98 are formed, are formed on the main surface of the first adhesive layer 12a on the side of the first wiring layer 16 and on the main surface of the second adhesive layer 14b on the side of the wiring layer 52. The solder balls 96 and 98 are formed in the openings 93 and 95. In this manner, the device mounting board 100 is formed. The device mounting board 100 may not includes the protection layers 92 and 94 or the solder balls 96 and 98.

As shown in FIG. 17C, the semiconductor module 300 is formed by placing on the side of the substrate structural unit 15a of the device mounting board 100 the semiconductor device 200 having the device electrode 210 and the device protection layer 220 and by electrically connecting the first wiring layer 16 and the device electrode 210 of the semiconductor device 200 through the solder ball 96. The semiconductor module 300 is mounted on the print wiring board 400 by placing the print wiring board 400 on the side of the substrate structural unit 15b of the semiconductor module 300 and by electrically connecting the wiring layer 52 and the board electrode 410 of the print wiring board 400 through the solder ball 98.

To summarize the functional effects obtained by the above-explained structure, the device mounting board 100 and the semiconductor module 300 of the embodiment are provided with the substrate structural unit 15a including the substrate 10a made of a composition containing amorphous silicon, the first adhesive layer 12a, and the second adhesive layer 14a. Similarly, they are also provided with the substrate structural unit 15b including the substrate 10b, the first adhesive layer 12b, and the second adhesive layer 14b. They have multi-layered wiring structures where the substrate structural unit 15a and the substrate structural unit 15b are laminated. As described above, since the substrate 10 having higher stiffness is used in the embodiment, the thickness thereof can be reduced. Thus, dry etching can be selected in forming the via holes 19 and 53 on the substrates 10a and 10b. As a result, multiple via holes 19 and 53 can be formed simultaneously, and the manufacturing time of the device mounting board 100 and the semiconductor module 300 can thus be shortened. Also, a via hole with less taper can be formed with high positional accuracy by dry etching. Thus, the narrow-pitch via holes 19 and 53 can be obtained.

The substrates 10a and 10b have compositions containing silicon approximately uniformly across the substrates. Thus, in forming the via holes 19 and 53, the via holes 19 and 53 having more uniform internal diameters can be formed, allowing the via holes 19 and 53 to have further reduced diameters and decreased pitches. The substrates 10a and 10b allow the electrical reliability of the device mounting board 100 to be improved since there is a small variation in the dielectric constants thereof.

Since the semiconductor device 200 is placed on the side of the substrate 10a having a small difference in the coefficient of thermal expansion from the semiconductor device 200, the difference in the coefficient of thermal expansion between the semiconductor device 200 and the device mounting board 100 can be reduced. Therefore, the thermal stress between the device mounting board 100 and the semiconductor device 200, for example, due to a thermal process caused when the semiconductor module 300 is mounted on the print wiring board 400 or due to a temperature change in the usage environment of an electronic device carrying the semiconductor module 300 can be reduced. Thus, the reliability of connection between the semiconductor device 200 and the device mounting board 100 can be improved. Since an insulating resin layer is not included, warpage of the device mounting board 100 due to heat can be prevented. A number of minute via holes can be formed throughout all the layers of the device mounting board 100 at high throughput.

Since a photocurable resin is used as an adhesive layer, the amount of heat applied can be reduced during the manufacturing of the device mounting board 100. With this, the warpage, and the like, of the device mounting board 100 due to the difference in the coefficient of thermal expansion between a substrate and a wiring layer at the time of manufacturing the device mounting board 100 can be prevented, and the connection reliability of the device mounting board 100 is improved.

### Embodiment 3

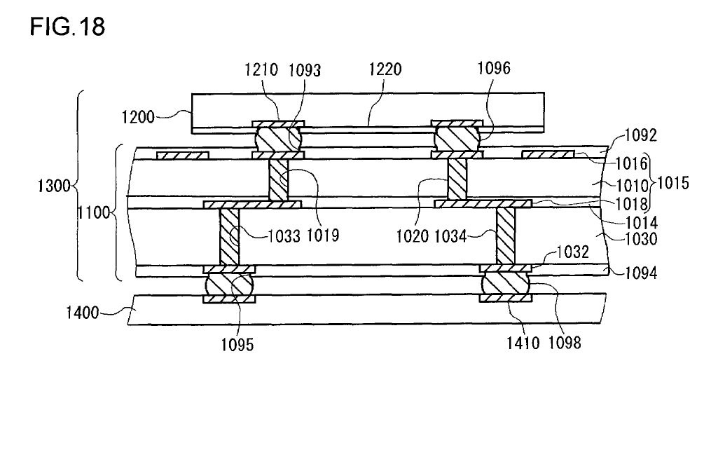

FIG. 18 is a schematic diagram showing a semiconductor module 1300, according to the embodiment 3, mounted on a print wiring board 1400. The semiconductor module 1300 is provided with a device mounting board 1100 and with a semiconductor device 1200 mounted on a device mounting board 1100.

The device mounting board 1100 is provided with a substrate 1010, a first wiring layer 1016 provided on one of the main surfaces of the substrate 1010, and a second wiring layer 1018 provided on the other main surface of the substrate 1010. A substrate structural unit 1015 (second substrate structural unit) is formed by the substrate 1010, the first wiring layer 1016, and the second wiring layer 1018. The device mounting board 1100 is provided with a via conductor 1020, which is provided in a via hole 1019 penetrating the substrate 1010, that electrically connects the first wiring layer 1016 and the second wiring layer 1018.

The substrate 1010 is made of a material similar to the material of the substrate 10 of the embodiment 1. Therefore, as the substrate 10, dry etching can be easily performed. Also, the substrate 1010 has a coefficient of thermal expansion closer to the coefficient of thermal expansion of the semiconductor device 1200.

The first wiring layer 1016 and the second wiring layer 1018 are formed by a conductive material, preferably only by electroless copper plating or by the combination of electroless copper plating and electrolytic copper plating. It may also be formed by the combination of sputtering and electrolytic copper plating. In the end area of the first wiring layer 1016, a land area is formed both for the placement of a solder ball 1096, which will be described hereinafter, on the main surface opposite from the glass substrate 1010 and for wiring.

The via conductor 1020 is provided in the via hole 1019 that penetrates the substrate 1010 at a predetermined position. In the embodiment, the via conductor 1020 is formed so as to fill in the via hole 1019. The via conductor 1020 is made of a conductive material and preferably of the same material used for the first wiring layer 1016 and the second wiring layer 1018.

The device mounting board 1100 of the embodiment is further provided with an insulating resin layer 1030, which is provided on the main surface of the substrate structural unit 1015, and with a wiring unit 1032, which is provided on the main surface of the insulating resin layer 1030 opposite from the substrate structural unit 1015. The device mounting board 1100 is provided with a via conductor 1034, which is provided in a via hole 1033 that penetrates the insulating resin layer 1030, that electrically connects the first wiring layer 1016 or second wiring layer 1018 with the wiring unit 0132. In this embodiment, the insulating resin layer 1030 is laminated on the main surface of the substrate structural unit 1015 on the side of the second wiring layer 1018, and the second wiring layer 1018 and the wiring unit 1032 are electrically connected by way of the via conductor 1034.

The insulating resin layer 1030 has a composition similar to that of the insulating resin layer 30 of the embodiment 1.

The wiring unit 1032 and the via conductor 1034 have structures similar to those of the above-stated first wiring layer 1016 and second wiring layer 1018 and of the via conductor 1020, respectively.

On the main surface of the first wiring layer 1016 opposite from the substrate 1010 and on the main surface of the wiring unit 1032 opposite from the insulating resin layer 1030, a protection layer 1092 and a protection layer 1094 are provided for the prevention of oxidation, etc., of the first wiring layer 1016 and the wiring unit 1032, respectively. The protection layers 1092 and 1094 include a solder resist layer and the like. In the predetermined areas of the protection layer 1092 and the protection layer 1094 that correspond to the land areas of the first wiring layer 1016 and the wiring unit 1032, an opening 1093 and an opening 1095 are formed, respectively. The land areas of the first wiring layer 1016 and the wiring unit 1032 are exposed through the openings 1093 and 1095. Solder balls 1096 and 1098 used as electrodes for external connection are formed in the openings 1093 and 1095, and the solder ball 1096 and the solder ball 1098 are electrically connected to the first wiring layer 1016 and the wiring unit 1032, respectively. The positions in which the solder balls 1096 and 1098 are formed, in other words, the forming areas of the openings 1093 and 1095 are, for example, the end areas where the wiring is extended by rewiring. In the embodiment, the solder balls 1096 and 1098 are provided as electrodes for external connection. Alternatively, connection to the semiconductor device 1200 and to the print wiring board 1400 may be achieved by wire bonding, etc.

The semiconductor module 1300 is formed with the semiconductor device 1200 mounted on the device mounting board 1100 having the above-mentioned structure. The semiconductor module 1300 of the embodiment is provided with the semiconductor device 1200 located on the side of the substrate structural unit 1015 of the device mounting board 1100, where the first wiring layer 1016 and a device electrode 1210 of the semiconductor device 1200 are electrically connected via the solder ball 1096.

The semiconductor device 1200 has the device electrode 1210 at a position opposite to the opening 1093 of the first wiring layer 1016. On the main surface of the semiconductor device 1200 on the side where the device electrode 1210 is provided, an insulating film (not shown) such as a silicon oxide film is provided. Furthermore, on the main surface of the semiconductor device 1200, which is on the insulating film, on the side of the substrate structural unit 1015, a device protection layer 1220 such as a polyimide layer, where an opening is provided so that the device electrode 1210 is exposed, is laminated. The specific examples of the semiconductor device 1200 include a semiconductor chip such as an integrated circuit (IC), a large-scale integrated circuit (LSI), and the like. For example, aluminum (Al) is used for the device electrode 210.

The semiconductor device 1200 is placed on the device mounting board 1100 on the side of the substrate structural unit 1015, and the semiconductor module 1300 in which the first wiring layer 1016 and the device electrode 1210 are electrically connected is placed so that the print wiring board 1400 is placed on the side of the insulating resin layer 1030. The wiring unit 1032 and a board electrode 1410 of the print wiring board 1400 are electrically connected via the solder ball 1098. This allows the semiconductor device 1200 to be mounted on the print wiring board 1400 via the device mounting board 1100.

### (The Manufacturing Method of a Device Mounting Board and a Semiconductor Module)

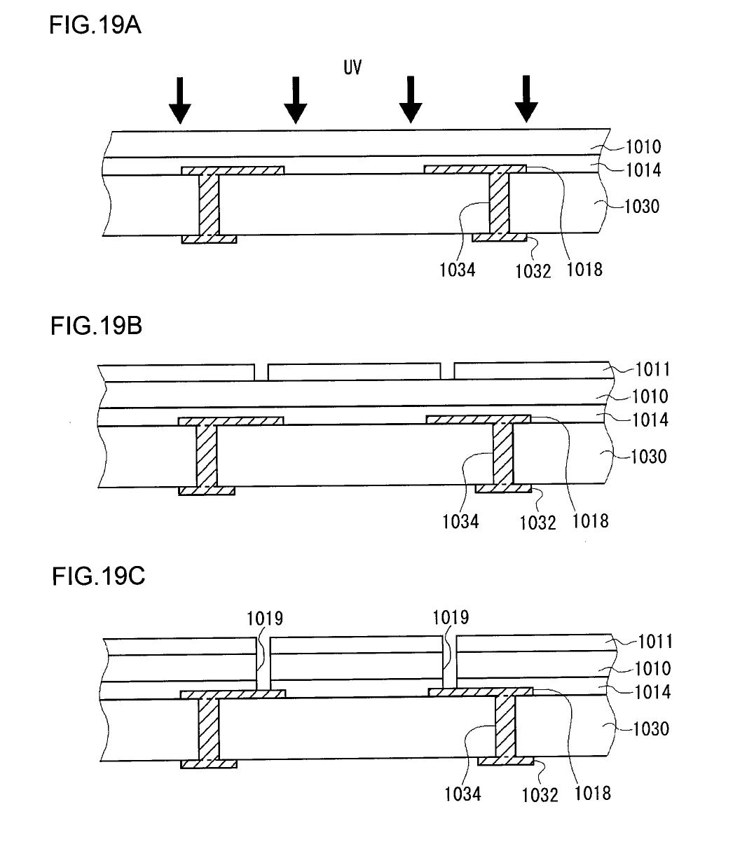

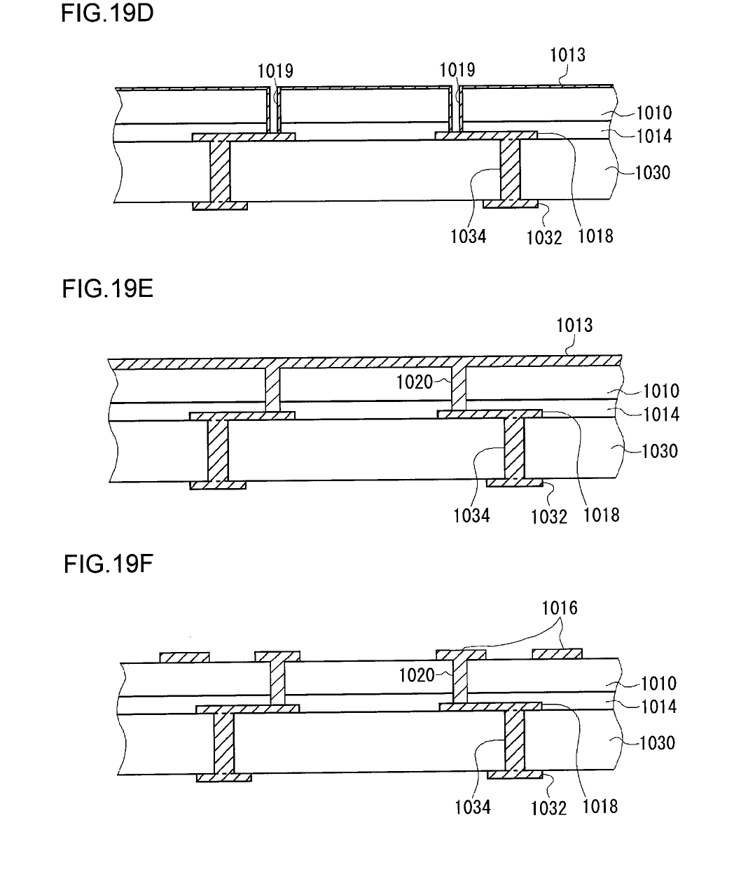

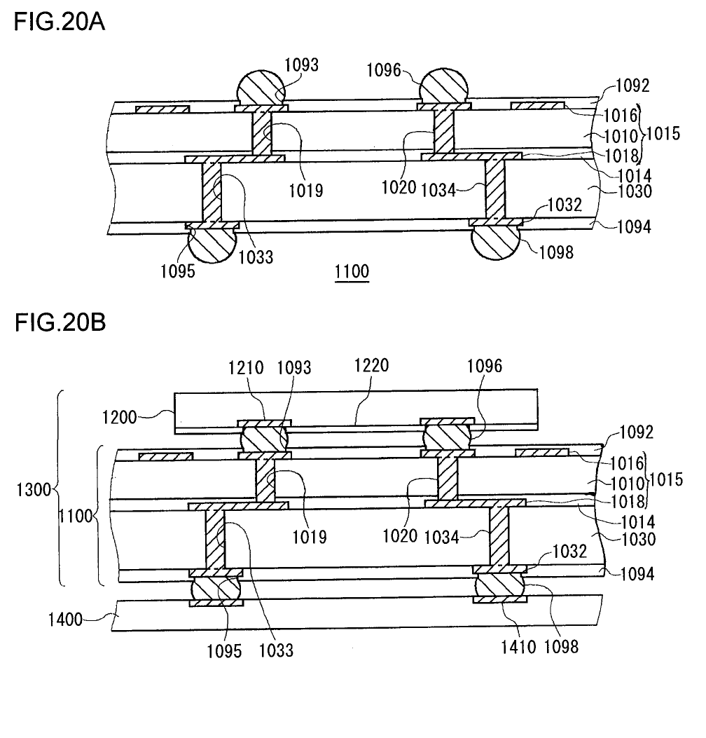

FIGS. 19A-19G and FIGS. 20A-20B are sectional views showing a manufacturing method of the device mounting board 1100 and the semiconductor module 1300.

By the same process shown in FIGS. 2A-2C and FIGS. 3A and 3B of the embodiment 1, the insulating resin layer 1030 is formed, provided with a via hole 1033, a via conductor 1034, the second wiring layer 1018, and the wiring unit 1032. The second wiring layer 1018, the insulating resin layer 1030, the wiring unit 1032, the via hole 1033, and the via conductor 1034 of the embodiment 3 correspond to the second wiring layer 18, the insulating resin layer 30, the wiring unit 32, the via hole 33, and the via conductor 34, respectively.

As shown in FIGS. 19A-19G, an explanation is now given of a circuit board 1400 based on the sectional views illustrating a manufacturing method of a circuit board 1015 of the device mounting board 1100, which has a glass board as a substrate.

As shown in FIG. 19A, a second adhesive layer 1014 and a glass substrate 1010 made of a glass are laminated in order on the main surface of the insulating resin layer 1030 on the side where the second wiring layer 1018 is formed. The adhesive layer 1014 is made of a material similar to the materials of the first adhesive layer 12 and the second adhesive layer 14 of the embodiment 1. The radiation of a UV ray on the adhesive layer 1014 from the side where the glass substrate 1010 is laminated hardens the adhesive layer 1014. This allows the substrate 1010 to be fixed to the insulating resin layer 1030 through the adhesive layer 1014.

As shown in FIG. 19B, a photoresist pattern 1011 is then formed on a predetermined position of the glass substrate 1010 so as to have an opening at the position corresponding to a via hole 1019 that will be formed during a later process.

As shown in FIG. 19C, the via hole 1019 is formed by performing dry etching on a glass by irradiating plasma. A requirement for plasma irradiation is, for example, to perform etching by supplying a gas having a flow rate of HBr/O₂: 50/4 sccm while the pressure inside a chamber is kept at 2 mTorr under the condition where a microwave is at 1800 w and where a bias high-frequency wave is at 20 w.

As shown in FIG. 19D, a seed layer 1013 made of a copper thin film having a thickness of a couple hundred nm is precipitated on the surface of the glass substrate 1010 including the sidewall surface of the via hole 1019 by, for example, a sputtering process or by the electroless plating of copper using palladium and the like as a catalyst.

As shown in FIG. 19E, the via conductor 1020 is formed, for example, by electrolytic copper plating using a copper sulfate solution as a plating solution. By this electrolytic copper plating, copper is deposited on the surface of the seed layer 1013, and the seed layer 1013 is thickened to achieve a predetermined thickness.

A photoresist pattern (not shown) is then selectively formed by a photolithography process in accordance with the pattern of the first wiring layer 1016. More specifically, a resist film having a predetermined thickness is pasted on the thickened seed layer 1013 by using a laminating device and is then exposed by using a photomask having the pattern of the first wiring layer 1016 and then developed so as to selectively form a resist on the thickened seed layer 13. In order to improve the closeness of contact with the resist, a pretreatment, such as grinding or washing, is desirably performed on the surface of the thickened seed layer 1013 before the lamination of a resist film. As shown in FIG. 19F, the first wiring layer 1016 having a predetermined wiring pattern on the glass substrate 1010 by performing etching on the thickened seed layer 1013 by using the resist as a mask.

Around the via conductor 1020 of the wiring layer 1016, the first wiring layer 1016 is in contact with the glass substrate 1010 around the via conductor 1020. In other words, the wiring layer 1016 covers the glass substrate 1010. Therefore, there is no adhesive layer between the first wiring layer 1016 and the glass substrate 1010 around the via conductor 1020. Thus, the thickness of the device mounting board and the semiconductor module can be reduced. The adhesive layer is made of a material similar to the materials of the first adhesive layer 12 and the second adhesive layer 14 of the embodiment 1.

As shown in FIG. 20A, in the device mounting board 1100 formed by adhesion, the protection layer 1092 and the protection layer 1094, which respectively have an opening 1093 and an opening 1095 in areas corresponding to the positions at which the solder balls 1096 and 1098 are formed, are formed on the main surface of the glass substrate 1010 on the side of the first wiring layer 1016 and on the main surface of the insulating resin layer 1030 on the side of the wiring unit 1032. The solder balls 1096 and 1098 are formed in the openings 1093 and 1095. In this manner, the device mounting board 1100 is formed. The device mounting board 1100 may not includes the protection layers 1092 and 1094 or the solder balls 1096 and 1098.

As shown in FIG. 20B, the semiconductor module 1300 is formed by placing on the side of the substrate structural unit 1015 of the device mounting board 1100 the semiconductor device 1200 having the device electrode 1210 and the device protection layer 1220 and by electrically connecting the first wiring layer 1016 and the device electrode 1210 of the semiconductor device 1200 through the solder ball 1096. The semiconductor module 1300 is mounted on the print wiring board 1400 by placing the print wiring board 1400 on the side of the insulating resin layer 1030 of the semiconductor module 1300 and by electrically connecting the wiring unit 1032 and the board electrode 1410 of the print wiring board 1400 through the solder ball 1098.

The thickness of the substrate 1010, the adhesive layer 1014, the first wiring layer 1016, the second wiring layer 1018, and the wiring unit 1032 of the embodiment are, for example, about 100-700 μm, about 20-30 μm, about 15-25 μm, about 15-25 μm, and about 15-25 μm, respectively. The diameters of the via conductor 1020 and the via conductor 1034 are, for example, about 50-700 μmφ and about 90-150 μmφ, respectively.

To summarize the functional effects obtained by the above-explained structure, the device mounting board 1100 and the semiconductor module 1300 of the embodiment are provided with the substrate structural unit 1015 including a substrate made of a composition containing an amorphous silicon, the first wiring layer 1016, and with the second wiring layer 1018. The first wiring layer 1016 and the second wiring layer 1018 are electrically connected by way of the via conductor 1020 provided in the via hole that penetrates the substrate 1010 and the adhesive layer 1014. As described above, the substrate 1010 is made of a composition containing amorphous silicon, for example, a glass consisting mainly of SiO₂ in the embodiment. It exhibits high material uniformity compared to a normal resin, for example, a resin containing fibers and fillers. Therefore, dry etching can be easily performed. Thus, in forming the via hole 1019 on the substrate 1010, dry etching can be selected. As a result, multiple via holes 1019 can be formed simultaneously, and the manufacturing time of the device mounting board 1100 and the semiconductor module 1300 can thus be shortened. Further increase in the future in the number of via holes to be formed allows the device mounting board 1100 of the embodiment to achieve more effects. Also, a via hole with less taper can be formed with high positional accuracy by dry etching, and narrow-pitch via holes 1019 formed on the substrate 1010 can thus be obtained.

While a conventional resin layer contains, for example, glass fibers to provide certain stiffness, the substrate 1010 has a composition containing silicon approximately uniformly across the substrate. Thus, when the via hole 1019 that penetrates the substrate 1010, the via hole 1019 that has a more uniform internal diameter can be formed. Thus, with regard to the via hole 1019 that is formed on the substrate 1010, the diameter and the pitch can be further decreased. The substrate 1010 allows the electrical reliability between the first wiring layer 1016 and the second wiring layer 1018 to be improved since there is a small variation in the dielectric constant thereof.

The device mounting board 1100 of the embodiment is further provided with an insulating resin layer 1030, which is provided on the main surface of the substrate structural unit 1015, and with a wiring unit 1032, which is provided on the main surface of the insulating resin layer 1030 opposite from the substrate structural unit 1015. The via conductor 1034 is provided in the via hole 1033 that penetrates the insulating resin layer 1030, and the wiring layer of the substrate structural unit 1015 and the wiring unit 1032 are electrically connected. The semiconductor device 1200 is placed on the side of the substrate 1010 having a smaller difference in the coefficient of thermal expansion from the semiconductor device 1200 compared to the insulating resin layer 1030, and the print wiring board 1400 is placed on the side of the insulating resin layer 1030 having a smaller difference in the coefficient of thermal expansion from the print wiring board 1400 compared to the substrate 1010. The semiconductor device 1200 and the print wiring board 1400 are electrically connected. Therefore, thermal stress, for example, due to a thermal process caused when the semiconductor module 1300 is mounted on the print wiring board 1400 or due to a temperature change in the usage environment of an electronic device carrying the semiconductor module 1300 can be reduced. Thus, the reliability of the connection between the semiconductor device 1200 and the print wiring board 1400 can be improved. This allows the reliability of the semiconductor module 300 and the electronic device, on which the semiconductor module is mounted, to be improved.

Since a photocurable resin is used as an adhesive layer, the amount of heat applied at the time of manufacturing the device mounting board 1100 can be reduced. With this, warpage and the like of the device mounting board 1100 due to the difference in the coefficient of thermal expansion among a substrate, a wiring layer, and an insulating resin layer at the time of manufacturing the device mounting board 1100 can be prevented, and the connection reliability of the device mounting board 1100 is improved. With regard to the wiring layer 1016 located around the via conductor 1020, the wiring layer 1016 is, while covering the substrate 1010, in direct contact with the substrate 1010 in the areas of the wiring layer having a width larger than the diameter of the via hole. Thus, there is no adhesive layer between the substrate 1010 and the wiring layer 1016. Therefore, the thickness thereof can be reduced also as a device mounting board. Similarly, the wiring layer 1016 located away from the via hole is also in direct contact with the substrate 1010 without any adhesive layer between them. Thus, the thickness of the device mounting board can be reduced.

(Exemplary Variation)

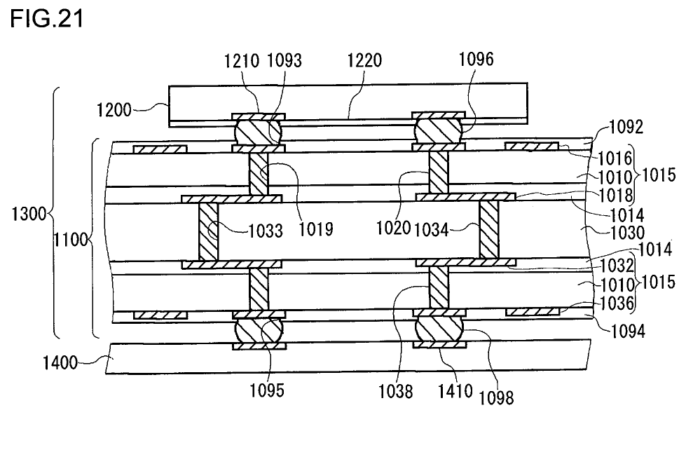

FIGS. 21, 22, 23, and 24 are schematic diagrams illustrating the semiconductor module 1300 mounted on the print wiring board 1400 according to the exemplary variation of the embodiment 3. As shown in FIGS. 21-24, the device mounting board 1100 can have a multi-layered wiring structure in which the substrate structural unit 1015 and the insulating resin layer 1030 are alternately laminated while a wiring layer is sandwiched between them. The other aspects are the same as the corresponding aspects of the embodiment 3.

The device mounting board 1100 according to the embodiment includes the first exemplary variation shown in FIG. 21. In other words, it is a structure where a second substrate structural unit 1015 is laminated on the main surface of the insulating resin layer 1030 on the side of the wiring unit 1032 in the device mounting board 1100 of the embodiment 3 and where the wiring layer 1036 is formed on the main surface of the second substrate structural unit 1015 on the opposite side from the insulating resin layer 1030. The wiring layer 1036 corresponds to the first wiring layer, and the wiring unit 1032 corresponds to the second wiring layer. The wiring unit 1032 and the wiring layer 1036 are electrically connected by way of the via conductor 1038.

This structure allows the difference in the coefficient of thermal expansion between the semiconductor device 1200 and the device mounting board 1100 to be reduced and also allows the warpage of the device mounting board 100 to be reduced since the device mounting board 1100 is sandwiched by the substrate structural units 1015 on both sides.

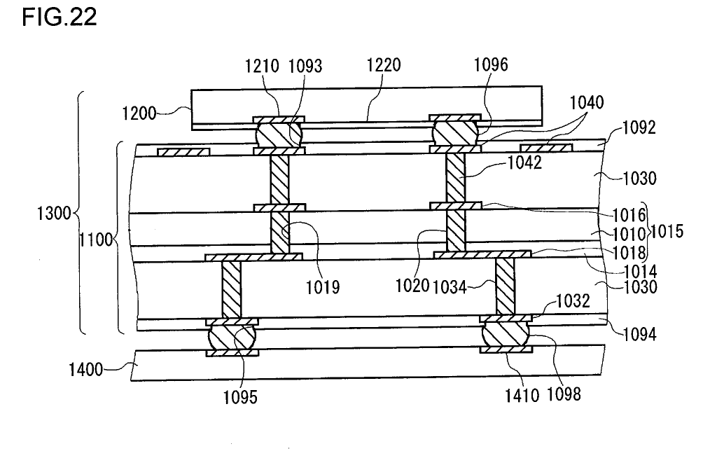

The device mounting board 1100 according to the embodiment includes the second exemplary variation shown in FIG. 22. In other words, it is a structure where a second insulating resin layer 1030 is laminated on the main surface of the substrate 1010 on the side of the first wiring layer 1016 in the device mounting board 1100 of the embodiment 3 and where the wiring layer 1040 is formed on the main surface of the second insulating resin layer 1030 on the opposite side from the substrate 1010. The first wiring layer 1016 and the wiring layer 1040 are electrically connected by way of the via conductor 1042. This structure allows the difference in the coefficient of thermal expansion between the device mounting board 1100 and the print wiring board 1400 to be reduced. Provided with the substrate structural units 1015, it also allows a number of minute via holes to be formed at high throughput.

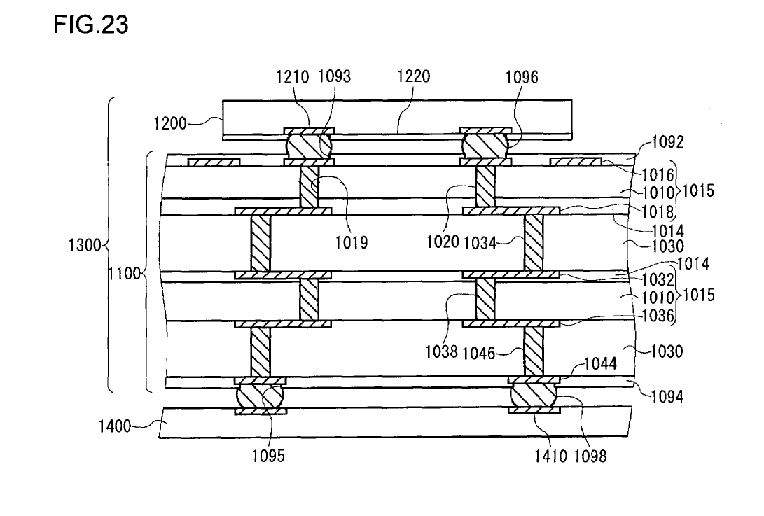

The device mounting board 1100 according to the embodiment includes the third exemplary variation shown in FIG. 23. In other words, it is a structure where a second insulating resin layer 1030 is laminated on the main surface of the second substrate structural units 1015 on the side of the wiring layer 1036 in the device mounting board 100 of the first exemplary variation shown in FIG. 21 and where the wiring layer 1044 is formed on the main surface of the second insulating resin layer 1030 on the opposite side from the second substrate structural units 1015. The wiring layer 1036 and the wiring layer 1044 are electrically connected by way of the via conductor 1046.

This structure allows the difference in the coefficient of thermal expansion between the semiconductor device 1200 and the device mounting board 1100 and the difference in the coefficient of thermal expansion between the device mounting board 1100 and the print wiring board 1400 to be reduced. Provided with the substrate structural unit 1015, a number of minute via holes can be formed at high throughput.

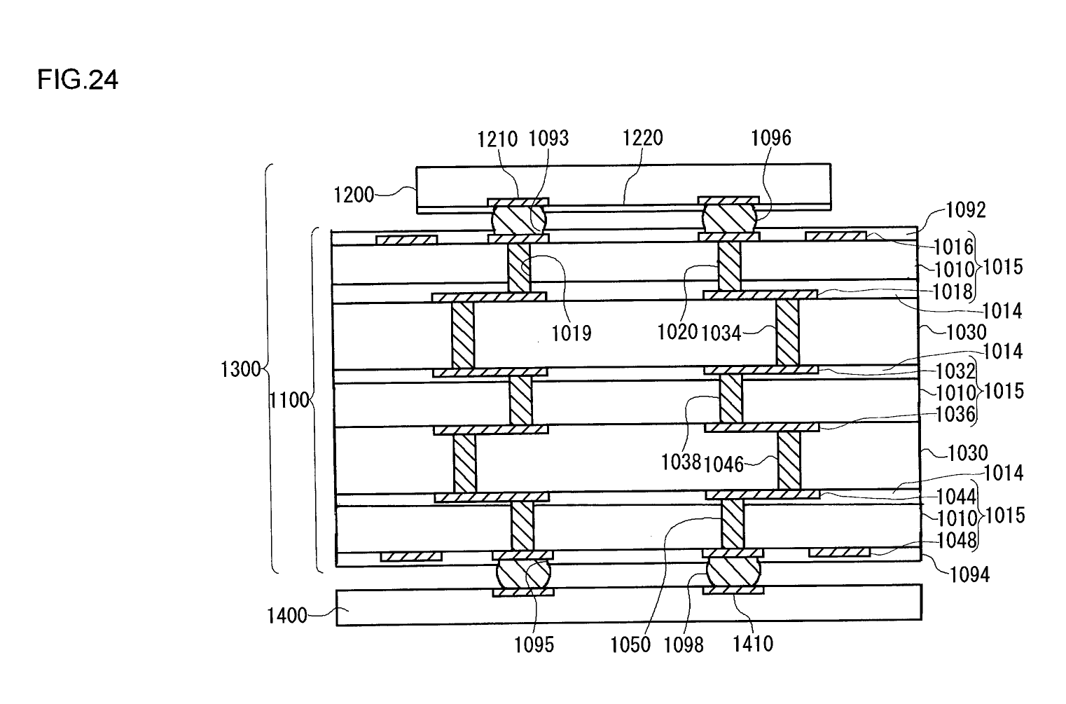

The device mounting board 1100 according to the embodiment includes a forth exemplary variation shown in FIG. 24. In other words, it is a structure where a third substrate structural unit 1015 is laminated on the main surface of the second insulating resin layer 1030 on the side of the wiring layer 1044 in the device mounting board 1100 of the third exemplary variation and where the wiring layer 1048 is formed on the main surface of the third substrate structural unit 1015 on the opposite side from the second insulating resin layer 1030. The wiring layer 1048 corresponds to the first wiring layer, and the wiring layer 1044 corresponds to the second wiring layer. The wiring layer 1044 and the wiring layer 1048 are electrically connected by way of the via conductor 1050.

This structure allows the difference in the coefficient of thermal expansion between the semiconductor device 1200 and the device mounting board 1100 to be reduced and also allows the warpage of the device mounting board 1100 to be reduced since the device mounting board 1100 is sandwiched by the substrate structural units 1015 on both sides. Provided with the substrate structural unit 1015, a number of minute via holes can be formed at high throughput.

### Embodiment 4

The device mounting board 1100 according to the embodiment 4 differs from the one according to the embodiment 3 in that the device mounting board 1100 has a multi-layered wiring structure where the substrate structural units 1015 are laminated in series.

The embodiment is now described in detail in the following. The other parts of the structure of the device mounting board 1100 and the structures of the semiconductor device 1200 and the print wiring board 1400 are basically the same as that of the embodiment 3. Like numerals represent like configurations in the embodiment 3, and the description thereof is simplified.

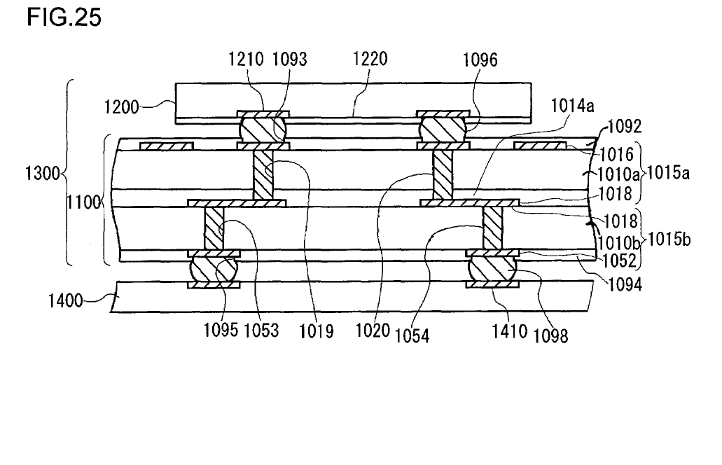

FIG. 25 is a schematic diagram showing a semiconductor module 1300, according to the embodiment 4, mounted on a print wiring board 1400. The semiconductor module 1300 is provided with the device mounting board 1100 and with the semiconductor device 1200 mounted on the device mounting board 1100.

The device mounting board 1100 is provided with a substrate structural unit 1015a including a substrate 101a, a first wiring layer 1016 provided on one of the main surfaces of a substrate 101a, and the second wiring layer 1018 provided on the other main surface of the substrate 1010a. The device mounting board 1100 is provided with a via conductor 1020, which is provided in a via hole 1019 that penetrates the substrate 1010a and the adhesive layer 1014a, that electrically connects the first wiring layer 1016 and the second wiring layer 1018.

The substrate 1010 is made of a composition containing amorphous silicon, for example, a glass consisting chiefly of SiO₂. Therefore, the substrate 1010 has a higher stiffness compared to a normal resin. Thus, the thickness thereof can be reduced. Thus, in forming the via hole 1019 on the substrate 1010, dry etching can be selected. Furthermore, compared to the insulating resin layer 1030, the substrate 1010 has a coefficient of thermal expansion closer to the coefficient of thermal expansion of the semiconductor device 1200.

The adhesive layer 1014a comprises, for example, photocurable resins. The photocurable resin is, for example, a UV-curable resin. The first wiring layer 1016 and the second wiring layer 1018 are formed by a conductive material, preferably a metal such as copper. The via conductor 1020 is provided in the via hole 1019 that penetrates the substrate 1010 and the adhesive layer 1014a at a predetermined position. The via conductor 1020 is made of a conductive material and preferably of the same material used for the first wiring layer 1016 and the second wiring layer 1018.

Substrate structural units 1015b are laminated in series in the device mounting board 1100 according to the embodiment. In other words, a substrate 1010b is laminated on the main surface of an adhesive layer 1014a on the opposite side from the substrate 1010a. A wiring layer 1052 is formed on the main surface of the substrate 1010b on the opposite side from the adhesive layer 1014a, and the second wiring layer 1018 and the wiring layer 1052 are electrically connected by way of a via conductor 1054 provided in a via hole 1053. The wiring layer 1052 and the via conductor 1054 have the structures similar to those of the above-stated first wiring layer 1016 and second wiring layer 1018 and of the via conductor 1020, respectively. As shown in FIG. 25, the substrate structural unit 1015a comprises the first wiring layer 1016, the substrate 1010a, and the second wiring layer 1018, and the substrate structural unit 1015b comprises the wiring layer 1052 (corresponding to the first wiring layer), the substrate 1010b, and the second wiring layer 1018. In other words, the device mounting board 1100 of the embodiment has a structure where the substrate structural unit 1015a and the substrate structural unit 1015b share the second wiring layer 1018. The structures of the embodiment where the two substrate structural units 1015 are laminated in series includes a structure as described above where two substrate structural units share a wiring layer.

On the main surface of the first wiring layer 1016 opposite from the substrate 1010a and on the main surface of the wiring layer 1052 opposite from the substrate 1010b, a protection layer 1092 and a protection layer 1094 are provided for the prevention of oxidation, etc., of the first wiring layer 1016 and the wiring layer 1052, respectively. In the predetermined areas of the protection layer 1092 and the protection layer 1094, the opening 1093 and the opening 1095 are formed, respectively. The solder balls 1096 and 1098 are formed in the openings 1093 and 1095 as electrodes for external connection. The solder ball 1096 and the solder ball 1098 are electrically connected to the first wiring layer 1016 and the wiring layer 1052, respectively.

The device mounting board 1100 having the above-stated structure and the semiconductor device 1200 are electrically connected by way of the solder ball 1096, and the device mounting board 1100 and the print wiring board 1400 are electrically connected by way of the solder ball 1098. This allows the semiconductor device 1200 to be mounted on the print wiring board 1400 via the device mounting board 1100.

### Embodiment 5

A mobile device provided with the semiconductor module of the present invention will be explained as follows. While a mobile phone is described to exemplify mobile devices, the inventive module may also be applied to electronic devices such as personal digital assistants (PDA), digital video cameras (DVC), and digital still cameras (DSC).

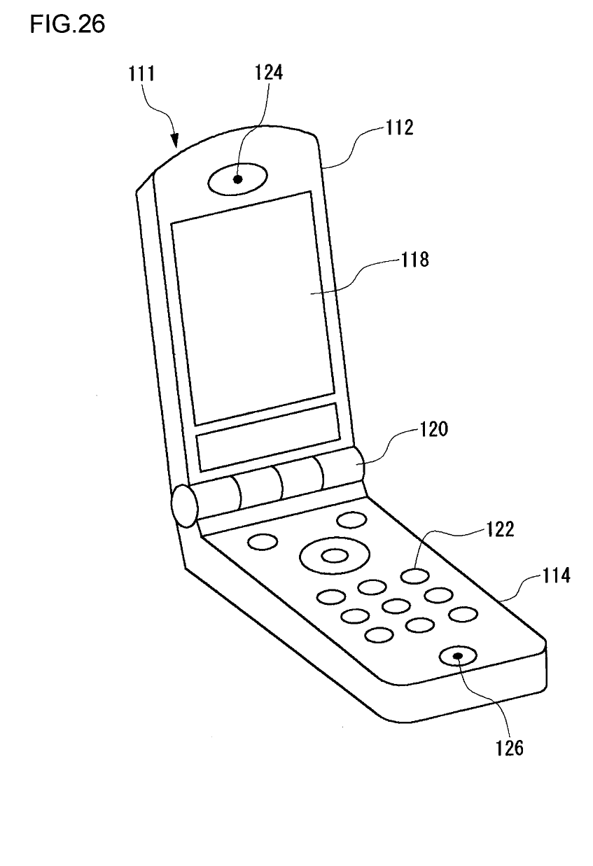

FIG. 26 shows the structure of a mobile phone provided with the semiconductor modules 300 and 1300 according to the embodiment. A mobile phone 111 is structured such that a first housing 112 and a second housing 114 are connected via a movable part 120. The first housing 112 and the second housing 114 are movable around the movable part 120. The first housing 112 is provided with a display unit 118, which is for displaying information including characters and images, and with a speaker unit 124. The second housing 114 is provided with a control 122 (e.g. control buttons) and a microphone unit 126. The semiconductor modules 300 and 1300, according to the respective embodiments, are mounted inside the mobile phone 111.

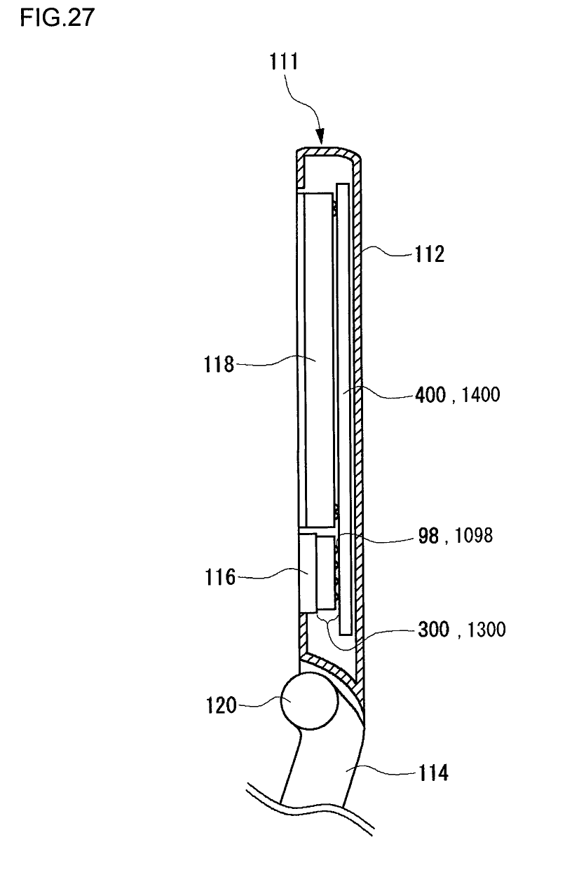

FIG. 27 is a partial section of the mobile phone shown in FIG. 26 (section of the first housing 112). The semiconductor modules 300 and 1300, according to the respective embodiments of the present invention, are mounted on the print wiring boards 400 and 1400 via the solder balls 98 and 1098 and electrically connected to, for example, the display unit 118 via the print wiring boards 400 and 1400. The undersides of the semiconductor modules 300 and 1300 (the surface opposite to the solder balls 98 and 1098) are provided with a heat spreader 116, such as a metal plate. For example, the heat generated by the semiconductor modules 300 and 1300 is prevented from collected inside the first housing 112 and is efficiently released outside the first housing 112.

The device mounting boards 100 and 1100 and the semiconductor modules 300 and 1300 according to the respective embodiments of the present invention allows for the manufacturing of the device mounting boards 100 and 1100 and the semiconductor modules 300 and 1300 at high throughput. Therefore, for a mobile device on which the semiconductor modules 300 and 1300 are mounted according to the embodiment, the manufacturing cost thereof can be reduced.

These embodiments are intended to be illustrative only, and it will be obvious to those skilled in the art that various modifications could be developed based on the knowledge of a skilled person and that such modifications are also within the scope of the present invention. The configuration of the present invention can be applied to a manufacturing process of a semiconductor package called a CSP (Chip Size Package) process. This allows for the thickness reduction and size reduction of a semiconductor module.

What is claimed is:

1. A device mounting board comprising:
a substrate made of a composition containing amorphous silicon;
an adhesive layer provided on at least either one of two main surfaces of the substrate;
a first wiring layer provided on the side of one of the main surfaces of the substrate;
a second wiring layer provided on the side of the other main surface of the substrate; and
a via conductor, which is provided in a via hole that penetrates the substrate and the adhesive layer, operative to electrically connect the first wiring layer and the second wiring layer.

2. The device mounting board according to claim 1 comprising:
a first substrate structural unit including a substrate made of a composition containing amorphous silicon, a first adhesive layer provided on one of the main surfaces of the substrate, and a second adhesive layer provided on the other main surface of the substrate;
a first wiring layer provided on the main surface of the first adhesive layer on the opposite side from the substrate;
a second wiring layer provided on the main surface of the second adhesive layer on the opposite side from the substrate; and
a via conductor, which is provided in a via hole that penetrates the substrate, the first adhesive layer, and the second adhesive layer, operative to electrically connect the first wiring layer and the second wiring layer.

3. The device mounting board according to claim 1 comprising:
a second substrate structural unit including a substrate made of a composition containing amorphous silicon, a first wiring layer provided on one of the main surfaces of the substrate, and a second wiring layer provided on the other main surface of the substrate; and
a via conductor, which is provided in a via hole that penetrates the substrate, operative to electrically connect the first wiring layer and the second wiring layer, wherein
a plurality of the second substrate structural units are laminated and an adhesive layer is placed between the substrates of the plurality of the second substrate structural units, and
the first wiring layer or the second wiring layer are, while covering the substrate, in contact with the substrate.

4. The device mounting board according to claim 3, wherein the first wiring layer or the second wiring layer are, while covering the substrate around the via hole, in contact with the substrate.

5. The device mounting board according to claim 2 comprising:
an insulating resin layer provided on the main surface of the first substrate structural unit;
a wiring layer provided on the main surface of the insulating resin layer on the opposite side from the first substrate structural unit; and
a via conductor, which is provided in a via hole that penetrates the insulating resin layer, operative to electrically connect the first wiring layer or the second wiring layer with the wiring unit.

6. The device mounting board according to claim 3 comprising:
an insulating resin layer provided on the main surface of the second substrate structural unit;
a wiring layer provided on the main surface of the insulating resin layer on the opposite side from the second substrate structural unit;
a via conductor, which is provided in a via hole that penetrates the insulating resin layer, operative to electrically connect the first wiring layer or the second wiring layer with the wiring unit.

7. The device mounting board according to claim 5, wherein a multi-layered wiring structure is formed by alternately laminating the first substrate structural unit and the insulating resin layer.

8. The device mounting board according to claim 6, wherein a multi-layered wiring structure formed by alternately laminating the second substrate structural unit and the insulating resin layer.

9. The device mounting board according to claim 5, wherein a multi-layered wiring structure is formed by laminating the first substrate structural units in series.

10. The device mounting board according to claim 6, wherein a multi-layered wiring structure is formed by laminating the second substrate structural units in series.

11. The device mounting board according to claim 2, wherein the substrate is a glass.

12. The device mounting board according to claim 3, wherein the substrate is a glass.

13. The device mounting board according to claim 2, wherein the first adhesive layer and the second adhesive layer are photocurable resins.

14. The device mounting board according to claim 3, wherein the adhesive layer is a photocurable resin.

15. A semiconductor module comprising:
the device mounting board according to claim 2; and
a semiconductor device having a device electrode electrically connected to the first wiring layer.

16. A semiconductor module comprising:
the device mounting board according to claim 3; and
a semiconductor device having a device electrode electrically connected to the first wiring layer.
